(19) United States
(12) Patent Application Publication
(10) Pub. No.: US 2025/0176173 A1
(43) Pub. Date: May 29, 2025

(54) SEMICONDUCTOR MEMORY DEVICE AND METHOD OF MANUFACTURING THE SAME

(71) Applicant: Samsung Electronics Co., Ltd., Suwon-si (KR)

(72) Inventors: Kyeonggyu LEE, Suwon-si (KR); Jinbum KIM, Suwon-si (KR); Suk YANG, Suwon-si (KR); Inhae ZOH, Suwon-si (KR); Wonhee CHOI, Suwon-si (KR)

(73) Assignee: Samsung Electronics Co., Ltd., Suwon-si (KR)

(21) Appl. No.: 18/924,442

(22) Filed: Oct. 23, 2024

(30) Foreign Application Priority Data
Nov. 23, 2023 (KR) 10-2023-0164785

(51) Int. Cl. H10B 12/00

(52) U.S. Cl. CPC H10B 12/485; H10B 12/05; H10B 12/315

(57) ABSTRACT

A semiconductor memory device includes a contact pad that fills a recess at an upper end of a channel region and is in contact with a contact plug, wherein sidewalls of the contact pad are spaced apart from a back gate dielectric film and a gate dielectric film with the channel region in between at a vertical level lower than a first vertical level at which an uppermost surface of the channel region is positioned.

### CROSS-REFERENCE TO RELATED APPLICATION

This application is based on and claims priority under 35 U.S.C. § 119 to Korean Patent Application No. 10-2023-0164785, filed on Nov. 23, 2023, in the Korean Intellectual Property Office, the disclosure of which is incorporated by reference herein in its entirety.

### BACKGROUND

The inventive concepts relate to semiconductor memory devices, and more particularly, to semiconductor memory devices including a vertical channel transistor.

Due to recent developments in electronic technology, down-scaling of semiconductor devices is rapidly progressing. Accordingly, miniaturization of memory cells is required. However, existing memory cells have limitations in maintaining high integration and reliability.

### SUMMARY

Some example embodiments of the inventive concepts provide a semiconductor memory device with improved reliability, and/or a method of manufacturing a semiconductor memory device with improved reliability. Such a semiconductor memory device may have a structure that facilitates miniaturization and high integration of memory cells.

According to some example embodiments of the inventive concepts, a semiconductor memory device may include a conductive line extending longitudinally in a first horizontal direction, a plurality of channel regions spaced apart from each other in the first horizontal direction on the conductive line and each defining a separate recess at an upper end thereof, a plurality of contact plugs spaced apart from the conductive line in a vertical direction such that the plurality of channel regions are between the plurality of contact plugs and the conductive line in the vertical direction, the vertical direction perpendicular to the first horizontal direction, a back gate electrode extending longitudinally in a second horizontal direction between a first channel region and a second channel region which are adjacent to each other and selected from among the plurality of channel regions, the second horizontal direction perpendicular to both the first horizontal direction and the vertical direction, a back gate dielectric film between the back gate electrode and the first channel region, a word line spaced apart from the back gate electrode in the first horizontal direction such that the first channel region is between the word line and the back gate electrode, a gate dielectric film between the word line and the first channel region, and a first contact pad that at least partially fills a recess defined by the first channel region and contacts a first contact plug selected from among the plurality of contact plugs and at least partially overlapping the first channel region in the vertical direction, wherein an uppermost surface of the first channel region is at a first vertical level, and sidewalls of the first contact pad are spaced apart from the back gate dielectric film and the gate dielectric film such that the first channel region includes a first portion between the first contact pad and the back gate dielectric film, and a second portion between the first contact pad and the gate dielectric film.

According to some example embodiments of the inventive concepts, a semiconductor memory device may include a conductive line extending longitudinally in a first horizontal direction, a back gate line, above the conductive line, spaced apart from the conductive line and extending longitudinally in a second horizontal direction perpendicular to the first horizontal direction, a first channel region and a second channel region respectively on opposite sides of the back gate line in the first horizontal direction, a word line above the conductive line, the word line spaced apart from the conductive line and spaced apart from the back gate line in the first horizontal direction such that the first channel region is between the conductive line and the back gate line in the first horizontal direction, a contact plug spaced apart from the conductive line in a vertical direction such that the first channel region is between the contact plug and the conductive line in the vertical direction, the vertical direction perpendicular to both the first horizontal direction and the second horizontal direction, a first dielectric film extending in the vertical direction between the first channel region and the back gate line and contacting the contact plug and the conductive line, a second dielectric film extending in the vertical direction between the first channel region and the word line and contacting the contact plug and the conductive line, and a first contact pad having an upper surface in contact with the contact plug and extending into the first channel region such that a width of the first contact pad in the first horizontal direction and a width of the first contact pad in the second horizontal direction decrease away from the contact plug, wherein an uppermost surface of the first channel region is located at the same vertical level as both an upper surface of the first dielectric film and an upper surface of the second dielectric film.

According to some example embodiments of the inventive concepts, a semiconductor memory device may include a plurality of conductive lines extending longitudinally in a first horizontal direction and spaced apart from each other in a second horizontal direction perpendicular to the first horizontal direction, a plurality of contact plugs spaced apart from the plurality of conductive lines in a vertical direction, the vertical direction perpendicular to both the first horizontal direction and the second horizontal direction, a plurality of channel regions positioned between the plurality of conductive lines and the plurality of contact plugs, each channel region of the plurality of channel regions including a first end connected to one conductive line of the plurality of conductive lines and a second end connected to one contact plug selected from among the plurality of contact plugs, a plurality of back gate electrodes extending in the second horizontal direction between the plurality of conductive lines and the plurality of contact plugs and spaced apart from each other in the first horizontal direction, a plurality of word lines extending longitudinally in the second horizontal direction between the plurality of conductive lines and the plurality of contact plugs and spaced apart from one selected from among the plurality of channel regions and one selected from among the plurality of back gate electrodes, a back gate dielectric film between a first back gate electrode selected from among the plurality of back gate electrodes and a first channel region selected from among the plurality of channel regions, a gate dielectric film between the first channel region and a first word line selected from among the plurality of word lines, the gate dielectric film spaced apart from the first back gate electrode such that the first channel region is between the gate dielectric film and the first back gate electrode, and a plurality of contact pads, each contact pad of the plurality of contact pads at least partially between the plurality of channel regions and the plurality of contact plugs, each contact pad of the plurality of contact pads including a portion extending into the plurality of channel regions, wherein an uppermost surface of the first end is at a first vertical level, and a first contact pad selected from among the plurality of contact pads is spaced apart from both the back gate dielectric film and the gate dielectric film at a vertical level lower than the first vertical level.

### BRIEF DESCRIPTION OF THE DRAWINGS

Example embodiments will be more clearly understood from the following detailed description taken in conjunction with the accompanying drawings in which:

FIG. 1 is a plan layout diagram of a partial configuration of a semiconductor memory device according to some example embodiments;

FIG. 2A is a cross-sectional view taken along line X1-X1′ of FIG. 1;

FIG. 2B is a cross-sectional view taken along line Y1-Y1′ of FIG. 1;

FIG. 3A is an enlarged cross-sectional view of a portion indicated as “EX1” in FIG. 2A;

FIG. 3B is an enlarged cross-sectional view of a portion indicated as “EX2” in FIG. 3A;

FIG. 3C is an enlarged cross-sectional view of a portion indicated as “EX3” in FIG. 2B;

FIGS. 4, 5, 6, 7, and 8 are cross-sectional views of semiconductor memory devices according to some example embodiments;

FIG. 9A is a plan layout diagram of a partial configuration of a semiconductor memory device according to some example embodiments;

FIG. 9B is a cross-sectional view taken along line X2-X2′ of FIG. 9A;

FIG. 9C is a cross-sectional view taken along line Y2-Y2′ of FIG. 9A;

FIG. 9D is an enlarged view of a portion indicated as “EX4” in FIG. 9B;

FIG. 9E is an enlarged view of a portion indicated as “EX5” in FIG. 9C; and

FIGS. 10A, 10B, 11, 12A, 12B, 13, 14A, 14B, 15A, 15B, 16, 17, 18A, 18B, 19, 20, 21, 22, 23, 24, 25, and 26 are diagrams showing a process sequence to explain a method of manufacturing a semiconductor memory device according to some example embodiments, wherein FIGS. 10A, 12A, 14A, 15A, and 18A are plan layout diagrams of partial configurations according to a process sequence to explain a method of manufacturing a semiconductor memory device, and FIGS. 10B, 11, 12B, 13, 14B, 15B, 16, 17, 18B, 19, 20, 21, 22, 23, 24, 25, and 26 are cross-sectional views of a portion corresponding to line X1-X1′ of FIG. 1 according to a process sequence.

### DETAILED DESCRIPTION

Hereinafter, some example embodiments are described in detail with reference to the accompanying drawings. The same reference numerals are used for the same components in the drawings, and duplicate descriptions thereof are omitted.

Herein, terms such as “first,” “second,” “third,” etc. are used to describe various elements, but these terms are not intended to limit the elements. These terms are only used to distinguish one component from another component, and unless specifically stated to the contrary, the first component may also be the second component or the third component. For example, without departing from the scope of the embodiments described below, a first channel region may be referred to as a second channel region or a third channel region, and similarly, the second channel region or the third channel region may be referred to as the first channel region. Although each of the first channel region, the second channel region, and the third channel region is a channel region, the first channel region, the second channel region, and the third channel region are not the same.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, an element that is “on” another element may be above, beneath, or horizontally next to (e.g., horizontally adjacent to) the other element and is not necessarily above an upper side of the other element based on a gravitational direction.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

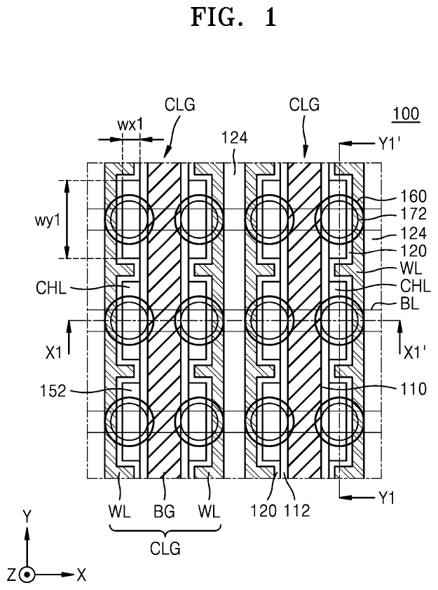

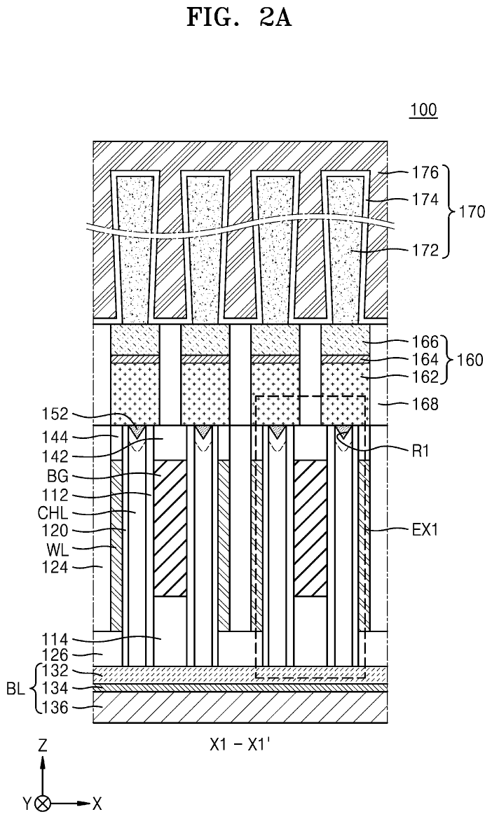

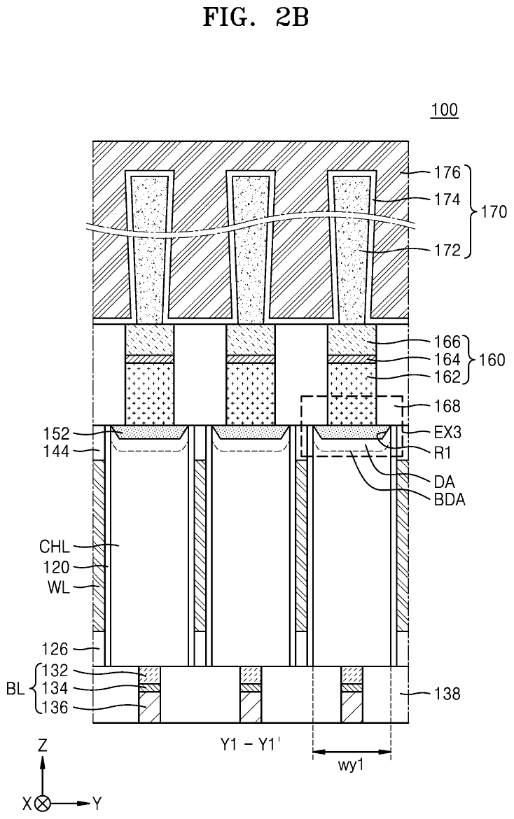

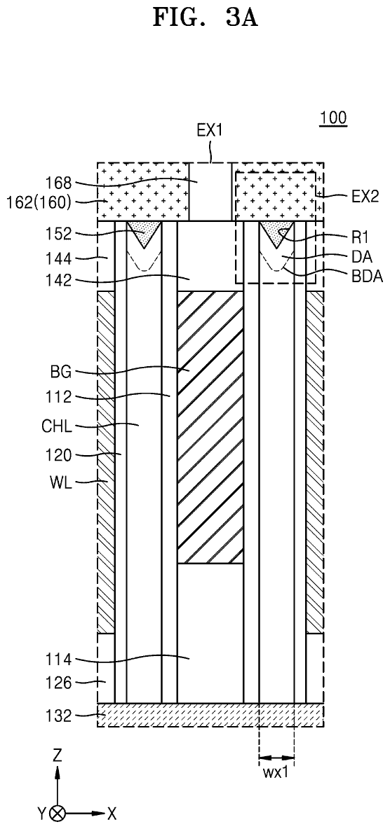

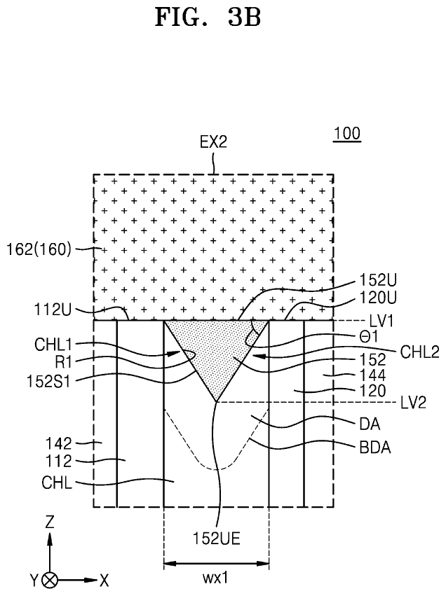

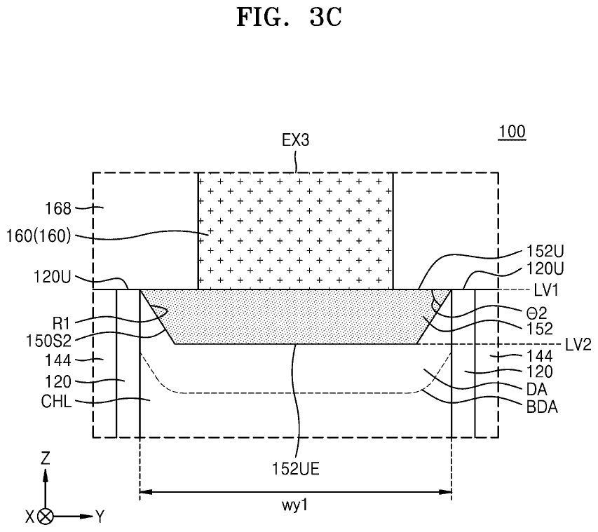

FIG. 1 is a plan layout diagram of a partial configuration of a semiconductor memory device 100 according to some example embodiments. FIG. 2A is a cross-sectional view taken along line X1-X1′ of FIG. 1. FIG. 2B is a cross-sectional view taken along line Y1-Y1′ of FIG. 1. FIG. 3A is an enlarged cross-sectional view of a portion indicated as “EX1” in FIG. 2A. FIG. 3B is an enlarged cross-sectional view of a portion indicated as “EX2” in FIG. 3A. FIG. 3C is an enlarged cross-sectional view of the portion indicated as “EX3” in FIG. 2B.

Referring to FIGS. 1 to 3C, the semiconductor memory device 100 may include a plurality of conductive lines BL that extend long in a first horizontal direction (X direction) and are repeatedly arranged and spaced apart from each other in a second horizontal direction (Y direction) perpendicular to the first horizontal direction (X direction). For example, the plurality of conductive lines BL may be spaced apart from each other in the second horizontal direction (Y direction) with a first interlayer insulating film 138 positioned in between. In the semiconductor memory device 100, each of the plurality of conductive lines BL may form a bit line.

The semiconductor memory device 100 may include a plurality of channel regions CHL positioned on the plurality of conductive lines BL and a plurality of contact plugs 160 positioned on the plurality of channel regions CHL. According to some example embodiments, the plurality of channel regions CHL on the plurality of conductive lines BL may be repeatedly arranged and spaced apart from each other in the first horizontal direction (X direction) and the second horizontal direction (Y direction). Each of the plurality of contact plugs 160 may be positioned on a corresponding channel region CHL among the plurality of channel regions CHL. Each of the plurality of channel regions CHL may extend in a vertical direction (Z direction) between one selected from among the plurality of conductive lines BL and one selected from among the plurality of contact plugs 160.

The plurality of conductive lines BL may each include metal, conductive metal nitride, metal silicide, doped polysilicon, or any combination thereof. For example, the plurality of conductive lines BL may each include Ti, TiN, Ta, TaN, Mo, Ru, W, WN, Co, Ni, TiSi, TiSiN, WSi, WSiN, TaSi, TaSiN, RuTiN, CoSi, NiSi, doped polysilicon, or any combination thereof. In some example embodiments, the first interlayer insulating film 138 may include a silicon oxide film, a silicon nitride film, or any combination thereof.

In some example embodiments, each of the plurality of conductive lines BL may include a first conductive line 132, a second conductive line 134, and a third conductive line 136 which are sequentially stacked on a lower surface of each the plurality of channel regions CHL, as illustrated in FIGS. 2A and 2B. For example, the first conductive line 132 may include doped polysilicon, the second conductive line 134 may include metal silicide, and the third conductive line 136 may include metal, but are not limited thereto.

Each of the plurality of channel regions CHL may include a first end and a second end that are opposite to each other in the vertical direction (Z direction). According to some example embodiments, in each of the plurality of channel regions CHL, the first end is connected to one contact plug 160 selected from among the plurality of contact plugs 160, and the second end may be connected to one conductive line BL selected from among the plurality of conductive lines BL.

The plurality of contact plugs 160 may be spaced apart from the plurality of conductive lines BL in the vertical direction (Z direction) with the plurality of channel regions CHL positioned in between. The plurality of contact plugs 160 may be arranged in a matrix arrangement to be spaced apart from each other in the first horizontal direction (X direction) and the second horizontal direction (Y direction). The plurality of contact plugs 160 may be connected to the plurality of channel regions CHL, respectively.

The plurality of contact plugs 160 may each include metal, conductive metal nitride, metal silicide, doped polysilicon, or any combination thereof. For example, the plurality of contact plugs 160 may each include Ti, TiN, Ta, TaN, Mo, Ru, W, WN, Co, Ni, TiSi, TiSiN, WSi, WSiN, TaSi, TaSiN, RuTiN, CoSi, NiSi, doped polysilicon, or any combination thereof.

In some example embodiments, the plurality of contact plugs 160 may include a first conductive pattern 162, a second conductive pattern 164, and a third conductive pattern 166 which are sequentially stacked on the plurality of channel regions CHL, as illustrated in FIGS. 2A and 2B. For example, the first conductive pattern 162 may include doped polysilicon, the second conductive pattern 164 may include metal silicide, and the third conductive pattern 166 may include metal, but are not limited thereto.

Each of the plurality of contact plugs 160 may penetrate a second interlayer insulating film 168 and contact the selected channel region CHL. The plurality of contact plugs 160 may be spaced apart from each other in the horizontal direction (X direction and/or Y direction) with the second interlayer insulating film 168 positioned in between. In some example embodiments, the second interlayer insulating film 168 may include a silicon oxide film, a silicon nitride film, or any combination thereof.

In some example embodiments, each of the plurality of channel regions CHL may include silicon (Si), for example, monocrystalline silicon, polycrystalline silicon, or amorphous silicon. In some example embodiments, the plurality of channel regions CHL may each include at least one selected from Ge, SiGe, SiC, GaAs, InAs, and InP. In some example embodiments, the channel region CHL may include a conductive region, for example, a well doped with impurities, or a structure doped with impurities.

According to some example embodiments, the semiconductor memory device 100 may include a plurality of back gate electrodes BG (in some example embodiments referred to as back gate lines) and a plurality of word lines WL which are positioned above each of the plurality of conductive lines BL. The plurality of back gate electrodes BG and the plurality of word lines WL may each extend long (also referred to herein interchangeably as extending longitudinally) in the second horizontal direction (Y direction) between the plurality of conductive lines BL and the plurality of contact plugs 160. The plurality of back gate electrodes BG may be spaced apart from the plurality of word lines WL in the first horizontal direction (X direction). According to some example embodiments, one of a plurality of conductive line groups CLG may include one back gate electrode BG among the plurality of back gate electrodes BG, and two word lines WL, among the plurality of word lines WL, positioned adjacent to the back gate electrode BG and spaced apart from each other in the first horizontal direction (X direction) with the first back gate electrode BG positioned in between. According to some example embodiments, the plurality of conductive line groups CLG on the plurality of conductive lines BL may be spaced apart from each other in the first horizontal direction (X direction) with a separation insulating pattern 124 positioned in between. For example, a pair of word lines WL included in each conductive line group CLG and spaced apart from each other in the first horizontal direction (X direction) with the separation insulating pattern 124 positioned in between may be arranged between each of the plurality of back gate electrodes BG. Herein, the word line WL may be referred to as a gate line and may be distinguished from the back gate electrode BG.

According to some example embodiments, each of the plurality of channel regions CHL on a corresponding conductive line BL among the plurality of conductive lines BL may be placed between one back gate electrode BG and one word line WL which are adjacent to each other in the first horizontal direction (X direction). According to some example embodiments, a pair of channel regions CHL are positioned on both sides of each of the plurality of back gate electrodes BG in the first horizontal direction (X direction), and a pair of word lines WL may be spaced apart from each of the plurality of back gate electrodes BG with the pair of channel regions CHL positioned in between.

According to some example embodiments, in each of the plurality of conductive line groups CLG, a plurality of pairs of channel regions CHL may be arranged in the second horizontal direction (Y direction) and may cover both sidewalls (e.g., opposite sidewalls) of one back gate electrode BG in the first horizontal direction (X direction). For example, the plurality of pairs of channel regions CHL may each be positioned on a corresponding conductive line BL among the plurality of conductive lines BL, and may be spaced apart from each other in the second horizontal direction (Y direction). In each of the plurality of conductive line groups CLG, a first word line WL of the two word lines WL may cover a first group of channel regions CHL covering a first sidewall of the back gate electrode BG among the plurality of pairs of channel regions CHL, and a second word line WL of the two word lines WL may cover a second group of channel regions CHL covering a second sidewall opposite to the first sidewall of the back gate electrode BG among the plurality of pairs of channel regions CHL. According to some example embodiments, each of the plurality of channel regions CHL may face one back gate electrode BG on one side, and may face one word line WL on the other side in the first horizontal direction (X direction).

According to some example embodiments, the first word line WL may include a plurality of first protrusions each positioned between a first group of channel regions CHL, and the first protrusions may face the back gate electrode BG in the first horizontal direction (X direction). The second word line WL may include a plurality of second protrusions each positioned between a second group of channel regions CHL, and the second protrusions may face the back gate electrode BG in the first horizontal direction (X direction). For example, the back gate electrode BG may include portions facing the plurality of pairs of channel regions CHL and portions facing the pair of word lines WL in the first horizontal direction (X direction).

In some example embodiments, the plurality of back gate electrodes BG may each include metal, conductive metal nitride, doped polysilicon, or any combination thereof. For example, the plurality of back gate electrodes BG may each include Ti, TiN, Ta, TaN, Mo, Ru, W, WN, TiSiN, WSiN, doped polysilicon, or any combination thereof, but are not limited thereto. The plurality of word lines WL may each include metal, conductive metal nitride, or any combination thereof. For example, the plurality of word lines WL may each include Ti, TiN, Ta, TaN, Mo, Ru, W, WN, TiSiN, WSiN, or any combination thereof, but are not limited thereto.

According to some example embodiments, the semiconductor memory device 100 may include a plurality of back gate dielectric films 112, where two of the plurality of back gate dielectric films 112 cover both sidewalls (e.g., opposite sidewalls) of each of the plurality of back gate electrodes BG in the first horizontal direction (X direction). Each of the plurality of back gate dielectric films 112 may be positioned between one back gate electrode BG and one channel region CHL adjacent thereto. For example, each of the plurality of back gate dielectric films 112 may be in contact with the back gate electrode BG and the channel region CHL. Each of the plurality of back gate dielectric films 112 (also referred to herein as a first dielectric film) may include one end in contact with the plurality of conductive lines BL and the other end partially in contact with the plurality of contact plugs 160 in the vertical direction (Z direction). For example, an upper surface 112U of each of the plurality of back gate dielectric films 112 may include a portion partially in contact with the first conductive pattern 162 of each of the plurality of contact plugs 160.

According to some example embodiments, a first capping insulating pattern 142 may be positioned between a pair of adjacent channel regions CHL, and between the back gate electrode BG and the plurality of contact plugs 160. A second capping insulating pattern 114 may be positioned between a pair of adjacent channel regions CHL, and between the back gate electrode BG and the conductive line BL. In some example embodiments, the first capping insulating pattern 142, the back gate electrode BG, and the second capping insulating pattern 114 may overlap with each other in the vertical direction (Z direction), and both sidewalls thereof in the first horizontal direction (X direction) may each be in contact with and covered by the back gate dielectric film 112. The back gate electrode BG may be spaced apart from the plurality of contact plugs 160 in the vertical direction (Z direction) with the first capping insulating pattern 142 positioned in between. The back gate electrode BG may be spaced apart from the plurality of conductive lines BL in the vertical direction (Z direction) with the second capping insulating pattern 114 positioned in between.

In some example embodiments, the first capping insulating pattern 142 and the second capping insulating pattern 114 may each include a silicon oxide film, a silicon nitride film, or any combination thereof. In some example embodiments, the first capping insulating pattern 142 and the second capping insulating pattern 114 may include different materials. For example, the first capping insulating pattern 142 may include a silicon oxide film, and the second capping insulating pattern 114 may include a silicon nitride film. In some example embodiments, the first capping insulating pattern 142 and the second capping insulating pattern 114 may include the same material.

According to some example embodiments, the semiconductor memory device 100 may include a plurality of gate dielectric films 120 (also referred to herein as second dielectric films) each positioned between the word line WL and the plurality of channel regions CHL adjacent thereto. A pair of gate dielectric films 120 may be positioned between a pair of channel regions CHL that are spaced apart from each other with the separation insulating pattern 124 in between and are adjacent to each other in the first horizontal direction (X direction). A pair of word lines WL may be positioned between the pair of gate dielectric films 120. Each of the pair of gate dielectric films 120 may be positioned between one word line WL and channel regions CHL positioned adjacent thereto and arranged in the second horizontal direction (Y direction) among the plurality of channel regions CHL, and may be in contact with the word line WL and the channel regions CHL. Each of the pair of gate dielectric films 120 may include one end in contact with the plurality of conductive lines BL and the other end partially in contact with the plurality of contact plugs 160. For example, the upper surface 120U of each of the plurality of gate dielectric films 120 may include a portion partially in contact with the first conductive pattern 162 of each of the plurality of contact plugs 160.

According to some example embodiments, one sidewall of each of the plurality of channel regions CHL in the first horizontal direction (X direction) may be in contact with one selected from among the plurality of back gate dielectric films 112, and the other sidewall may be in contact with one selected from among the plurality of gate dielectric films 120. According to some example embodiments, both sidewalls of each of the plurality of channel regions CHL in the second horizontal direction (Y direction) may be in contact with a corresponding gate dielectric film 120 among the plurality of gate dielectric films 120, and may face a corresponding word line WL among the plurality of word lines WL with the gate dielectric film 120 positioned in between.

According to some example embodiments, the separation insulating pattern 124 may be positioned between the pair of word lines WL between the pair of adjacent channel regions CHL. A pair of first buried insulating patterns 144 may be positioned between the pair of word lines WL and the plurality of contact plugs 160, and a second buried insulating pattern 126 may be positioned between the pair of word lines WL and the conductive line BL. The pair of first buried insulating patterns 144 may be spaced apart from each other in the first horizontal direction (X direction) with the separation insulating pattern 124 positioned in between. Between the pair of adjacent channel regions CHL, the pair of word lines WL, the pair of first buried insulating patterns 144, and the pair of second buried insulating patterns 126 may overlap with each other in the vertical direction (Z direction). The pair of word lines WL may be spaced apart from the plurality of contact plugs 160 in the vertical direction (Z direction) with the pair of first buried insulating patterns 144 positioned in between. The pair of word lines WL and the separation insulating pattern 124 may be spaced apart from the plurality of conductive lines BL with the second buried insulating pattern 126 positioned in between.

In some example embodiments, the separation insulating pattern 124, the first buried insulating pattern 144, and the second buried insulating pattern 126 may each include a silicon oxide film, a silicon nitride film, or any combination thereof. In some example embodiments, the separation insulating pattern 124, the first buried insulating pattern 144, and the second buried insulating pattern 126 may include different materials. In some example embodiments, the separation insulating pattern 124, the first buried insulating pattern 144, and the second buried insulating pattern 126 may include the same material.

According to some example embodiments, the gate dielectric film 120 and the back gate dielectric film 112 may each include a silicon oxide film, a high-k dielectric film, or any combination thereof. The high-k dielectric film refers to a film having a higher dielectric constant than a silicon oxide film. In some example embodiments, the gate dielectric films 120 and the back gate dielectric films 112 may each include at least one material selected from silicon oxide, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO). The plurality of back gate electrodes BG, the plurality of word lines WL, the plurality of channel regions CHL, the plurality of back gate dielectric films 112, and the plurality of gate dielectric films 120 which are positioned between the plurality of conductive lines BL and the plurality of contact plugs 160 may form a plurality of vertical channel transistors.

As illustrated in FIGS. 1, 2A, and 2B, a capacitor structure 170 may be positioned on the plurality of contact plugs 160 and the second interlayer insulating films 168. The capacitor structure 170 may include a plurality of lower electrodes 172, a capacitor dielectric film 174 that conformally covers surfaces of each of the plurality of lower electrodes 172, and an upper electrode 176 that covers the plurality of lower electrodes 172 with the capacitor dielectric film 174 positioned in between. Each of the plurality of lower electrodes 172 may be connected to the channel region CHL through one contact plug 160 selected from among the plurality of contact plugs 160. The third conductive pattern 166 included in each of the plurality of contact plugs 160 may function as a landing pad in contact with one lower electrode 172 selected from among the plurality of lower electrodes 172.

According to some example embodiments, the semiconductor memory device 100 may include a plurality of contact pads 152 that each fill a recess R1 formed at (e.g., defined by one or more surfaces of) a first end of each of the plurality of channel regions CHL in the vertical direction (Z direction). One of the plurality of contact pads 152 may be positioned between each of the plurality of channel regions CHL and a corresponding contact plug 160 among the plurality of contact plugs 160. In some example embodiments, the first end of each of the plurality of channel regions CHL may be in contact with a corresponding contact pad 152 among the plurality of contact pads 152, and may face a corresponding contact plug 160 among the plurality of contact plugs 160 with the contact pad 152 positioned in between. In some example embodiments, an upper surface 152U of each of the plurality of contact pads 152 may be in contact with a corresponding contact plug 160 among the plurality of contact plugs 160. In some example embodiments, a second end opposite to the first end of each of the plurality of channel regions CHL may be in contact with one conductive line BL selected from among the plurality of conductive lines BL.

In some example embodiments, each of the plurality of channel regions CHL may have a first width wx1 in the first horizontal direction (X direction) and a second width wy1 in the second horizontal direction (Y direction). In some example embodiments, uppermost surfaces of the plurality of channel regions CHL may be positioned at a first vertical level LV1, and the upper surface 112U of each of the plurality of back gate dielectric films 112 and the upper surface 120U of each of the plurality of gate dielectric films 120 may be positioned at the first vertical level LV1. At the first vertical level LV1, an area of the recess R1 may be limited by the back gate dielectric film 112 and the gate dielectric film 120 which surround the recess R1. For example, at the first vertical level LV1, a width of the recess R1 in the first horizontal direction (X direction) may be substantially the same as the first width wx1, and a width of the recess R1 in the second horizontal direction (Y direction) may be substantially the same as the second width wy1.

In some example embodiments, the upper surface 152U of each of the plurality of contact pads 152 may be parallel to the upper surface 112U of each of the plurality of back gate dielectric films 112 and the upper surface 120U of each of the plurality of gate dielectric films 120. In some example embodiments, the upper surface 152U of each of the plurality of contact pads 152 may be coplanar with the upper surface 112U of each of the plurality of back gate dielectric films 112 and the upper surface 120U of each of the plurality of gate dielectric films 120. For example, the upper surface 152U of each of the plurality of contact pads 152 may be positioned at the first vertical level LV1. At the first vertical level LV1, a width of each of the plurality of contact pads 152 in the first horizontal direction (X direction) may be substantially the same as the first width wx1, and a width of each of the plurality of contact pads 152 in the second horizontal direction (Y direction) may be substantially the same as the second width wy1. It will be understood that, as referred to herein, a vertical level, level, etc. of an element may refer to a distance of the element from a reference location (e.g., an upper surface of a first conductive line 132) in the vertical direction (Z direction).

In some example embodiments, the plurality of contact plugs 160 may have the shape of a circular plane, and a horizontal width of each of the plurality of contact plugs 160 may be greater than the first width wx1 and smaller than the second width wy1. In some example embodiments, the upper surface 152U of each of the plurality of contact pads 152 may include a portion in contact with the second interlayer insulating films 168.

In some example embodiments, inner walls of the recess R1 may include a plurality of planes. For example, the plurality of planes may form an angle at a point where the planes meet. In some example embodiments, the inner walls of the recess R1 may be formed of a single crystal plane. For example, among crystal planes in various directions that the channel region CHL may have when forming the recess R1, a crystal plane in the first direction may function as an etch stop plane. The recess R1 having inner walls including the crystal plane in the first direction may be formed by removing parts having planes other than the crystal plane in the first direction. Referring to FIGS. 3B and 3C, the inner walls of the recess R1 may have the crystal plane in the first direction, and may face sidewalls 152S1 and 152S2 of each of the plurality of contact pads 152. For example, the plurality of channel regions CHL may include Si, and the inner walls of the recess R1 may include a (111) crystal plane. In some example embodiments, the plurality of contact pads 152 may each have the shape of a polyhedron that at least partially fills the recess R1. In some example embodiments, at least some of the plurality of planes forming the inner walls of the recess R1 may have crystal planes in different directions.

In some example embodiments, each of both inner walls of the recess R1 in the first horizontal direction (X direction) may have a first angle θ1 with respect to the upper surface 112U of each of the plurality of back gate dielectric films 112 and the upper surface 120U of each of the plurality of gate dielectric films 120. Both inner walls of the recess R1 in the second horizontal direction (Y direction) may have a second angle θ2 with respect to the upper surface 112U of each of the plurality of gate dielectric films 112.

In some example embodiments, both sidewalls 152S1 of each of the plurality of contact pads 152 in the first horizontal direction (X direction) may have the first angle θ1 with respect to the upper surface 112U of each of the plurality of back gate dielectric films 112 and the upper surface 120U of each of the plurality of gate dielectric films 120. In some example embodiments, both sidewalls 152S2 of each of the plurality of contact pads 152 in the second horizontal direction (Y direction) may have the second angle θ2 with respect to the upper surface 112U of each of the plurality of gate dielectric films 112.

In some example embodiments, the first angle θ1 and the second angle θ2 may be the same. In some example embodiments, the first angle θ1 and the second angle θ2 may be different. In FIGS. 3B and 3C, it is illustrated that both inner walls of the recess R1 in the first horizontal direction (X direction) have the first angle θ1 with respect to the upper surface 112U of each of the plurality of back gate dielectric films 112 and the upper surface 120U of each of the plurality of gate dielectric films 120, but is not limited thereto. For example, both inner walls of the recess R1 in the first horizontal direction (X direction) may have different angles with respect to the upper surface 112U of each of the plurality of back gate dielectric films 112 and the upper surface 120U of each of the plurality of gate dielectric films 120, and both inner walls of a recess R2 in the first horizontal direction (X direction) may have different angles with respect thereto.

According to some example embodiments, each of the plurality of contact pads 152 may extend into a corresponding channel region CHL among the plurality of channel regions CHL. According to some example embodiments, the sidewalls 152S1 and 152S2 of each of the plurality of contact pads 152 may be surrounded by the corresponding channel region CHL. In some example embodiments, a width of each of the plurality of contact pads 152 in a horizontal direction (X direction and/or second horizontal direction) may decrease toward the plurality of conductive lines BL. For example, each of the plurality of contact pads 152 may extend into the corresponding channel region CHL, and the first sidewalls 152S1 of each of the plurality of contact pads 152 in the first horizontal direction (X direction) may extend to be inclined with respect to the first horizontal direction (X direction) and the vertical direction (Z direction), respectively. For example, the second sidewalls 152S2 of each of the plurality of contact pads 152 in the second horizontal direction (Y direction) may extend to be inclined with respect to the second horizontal direction (Y direction) and the vertical direction (Z direction), respectively.

In some example embodiments, each of the plurality of contact pads 152 may be in line contact (e.g., linear contact) with the back gate dielectric film 112 and the gate dielectric film 120 which are adjacent thereto at the first vertical level LV1. For example, a first side of each of the plurality of contact pads 152 in the first horizontal direction (X direction) may be in line contact with the back gate dielectric film 112 at the first vertical level LV1, and a second side opposite to the first side in the first horizontal direction (X direction) may be in line contact with the gate dielectric film 120 at the first vertical level LV1. For example, both sides of each of the plurality of contact pads 152 in the second horizontal direction (Y direction) may each be in line contact with the gate dielectric film 120 at the first vertical level LV1.

In some example embodiments, a distance between the first sidewalls 152S1 of each of the plurality of contact pads 152 and the adjacent back gate dielectric film 112 or a distance between the first sidewalls 152S1 thereof and the adjacent gate dielectric film 120 in the first horizontal direction (X direction) may increase away from the upper surface 152U thereof. In some example embodiments, a distance between the second sidewalls 152S2 of each of the plurality of contact pads 152 and the adjacent gate dielectric film 120 in the second horizontal direction (Y direction) may increase away from the upper surface 152U thereof.

In some example embodiments, the first sidewalls 152S1 of each of the plurality of contact pads 152 may be spaced apart from the back gate dielectric film 112 and the gate dielectric film 120, respectively, which face the corresponding channel region CHL at a vertical level lower than the first vertical level LV1. As shown, the corresponding channel region CHL may include a first portion CHL1 between the contact pad 152 and the back gate dielectric film 112 and a second portion CHL2 between the contact pad and the gate dielectric film 120. In some example embodiments, the second sidewalls 152S2 of each of the plurality of contact pads 152 may be spaced apart from the gate dielectric film 120 facing the corresponding channel region CHL at a vertical level lower than the first vertical level LV1.

In some example embodiments, the lowermost surface of the plurality of contact pads 152 may be positioned at a second vertical level LV2 that is lower than the first vertical level LV1. In some example embodiments, each of the plurality of channel regions CHL between the first vertical level LV1 and the second vertical level LV2 may include a corresponding contact pad 152 among the plurality of contact pads 152 and surrounding dielectric films, e.g., a portion positioned between the back gate dielectric film 112 and the gate dielectric film 120.

In some example embodiments, the sidewalls 152S1 and 152S2 of each of the plurality of contact pads 152 may extend linearly. In some example embodiments, the first width wx1 and the second width wy1 of each of the plurality of channel regions CHL may be different from each other. For example, the second width wy1 may be greater than the first width wx1. In some example embodiments, the first sidewalls 152S1 of each of the plurality of contact pads 152 may meet at the second vertical level LV2 to form an edge 152UE. In some example embodiments, the second sidewalls 152S2 of each of the plurality of contact pads 152 may meet at the second vertical level LV2 and contact both ends of the edge 152UE. In some example embodiments, the edge 152UE may extend in the second horizontal direction (Y direction). For example, the upper surface 152U of each of the plurality of contact pads 152 may have the shape of a rectangular plane, the first sidewalls 152S1 may have the shape of an equilateral trapezoid, and the second sidewalls 152S2 may have the shape of an isosceles triangle. For example, the plurality of contact pads 152 may have the shape of a pentahedron having the edge 152UE at the second vertical level LV2.

In some example embodiments, the upper surface 152U of each of the plurality of contact pads 152 may be positioned at the first vertical level LV1, and may be in contact with a corresponding contact plug 160 among the plurality of contact plugs 160. For example, the upper surface of the plurality of channel regions CHL, the upper surface 152U of the plurality of contact pads 152, the upper surface 112U of the plurality of back gate dielectric films 112, and the upper surface 120U of the plurality of gate dielectric films 120 may be coplanar with each other.

In some example embodiments, the upper surface 152U of each of the plurality of contact pads 152 may be positioned at the first vertical level LV1, and a width of the upper surface 152U thereof in the horizontal direction (X direction and/or Y direction) may be limited by the back gate dielectric film 112 and the gate dielectric film 120.

Referring to FIGS. 2A to 3C, the plurality of channel regions CHL may include doped areas DA in contact with the plurality of contact pads 152. For example, the doped areas DA may be formed through diffusion of a dopant, and the dopant may include an N-type dopant or a P-type dopant. The doped areas DA may function as source/drain areas in the plurality of vertical channel transistors. In FIGS. 2A to 3C, it is illustrated that the doped area DA is formed only at one end of the plurality of channel regions CHL, but is not limited thereto. For example, the doped area may be formed at the other end of the plurality of channel regions CHL connected to the conductive line BL.

In some example embodiments, the plurality of contact pads 152 may include a semiconductor film doped with a dopant. For example, the plurality of contact pads 152 may include a semiconductor film epitaxially grown from the inner walls of the recess R1. For example, the dopant may include an N-type dopant or a P-type dopant. The dopant may include, for example, at least one selected from P, B, and As. In some example embodiments, the plurality of contact pads 152 may each include a silicon film doped with As and P. Since the plurality of contact pads 152 include As, the diffusion rate of the dopant may be more easily controlled and the doping concentration of the doped area DA in the vertical direction (Z direction) may be uniformly controlled. In some example embodiments, the plurality of contact pads 152 may include a material different from that of the first conductive pattern 162. In some example embodiments, the plurality of contact pads 152 may include the same material as the first conductive pattern 162, and in this case, the plurality of contact pads 152 and the first conductive pattern 162 may have an integrated structure.

In some example embodiments, a boundary BDA of the doped area DA may correspond to the shape of the sidewalls 152S of each of the plurality of contact pads 152. For example, the boundary BDA of the doped area DA may have a profile corresponding to surfaces of the sidewalls 152S1 and 152S2 of each of the plurality of contact pads 152 moved in parallel in the vertical direction (Z direction). In some example embodiments, a concentration contour line of the dopant in the doped area DA may have a profile corresponding to the boundary BDA of the doped area DA. For example, the concentration contour line thereof may have a profile corresponding to a parallel movement of the surfaces of the sidewalls 152S1 and 152S2 of each of the plurality of contact pads 152 in the vertical direction (Z direction). The boundary BDA of the doped area DA may have a convex curved surface facing the conductive line BL, similar to the shape of the plurality of contact pads 152. For example, a portion of the boundary BDA of the doped area DA that overlaps the edge 152UE of the contact pad 152 in the vertical direction (Z direction) may be located at a vertical level lower than portions thereof that is in contact with the dielectric films, e.g., the back gate dielectric film 112 and gate dielectric film 120, and the boundary BDA of the doped area DA may have a curved surface that is convex downward.

In a semiconductor memory device according to a comparative example, the sidewalls of the back gate dielectric film 112 and the gate dielectric film 120 are in full contact with the plurality of contact plugs 160, and an electrically non-functional dopant cluster is formed at the contact interface when the dopant diffuses, resulting in a deterioration in the performance of the semiconductor memory device according to the comparative example. In the semiconductor memory device according to the comparative example, the dopant forming the doped area diffuses at a relatively high speed along the sidewalls of the back gate dielectric film 112 and the gate dielectric film 120, so that the concentration profile according to the thickness of the doped area is not formed uniformly, thereby reducing electrical reliability. For example, in the semiconductor memory device according to the comparative example, the portion of the boundary BDA of the doped area DA that overlaps with the edge 152UE of the contact pad 152 in the vertical direction (Z direction) may be located at a vertical level higher than the portion of the boundary BDA of the doped area DA that is in contact with the back gate dielectric film 112 and the gate dielectric film 120, and the boundary BDA of the doped area DA may have a curved surface that is convex upward.

Since the semiconductor memory device 100 according to some example embodiments includes the plurality of contact pads 152 with a reduced contact area with the back gate dielectric film 112 and the gate dielectric film 120, dopant diffusion may be performed uniformly depending on the thickness of the doped area even in the case of a vertical transistor structure with a very thin body due to downscaling, and the diffusion range may be easily controlled, thereby providing the semiconductor memory device 100 with improved reliability.

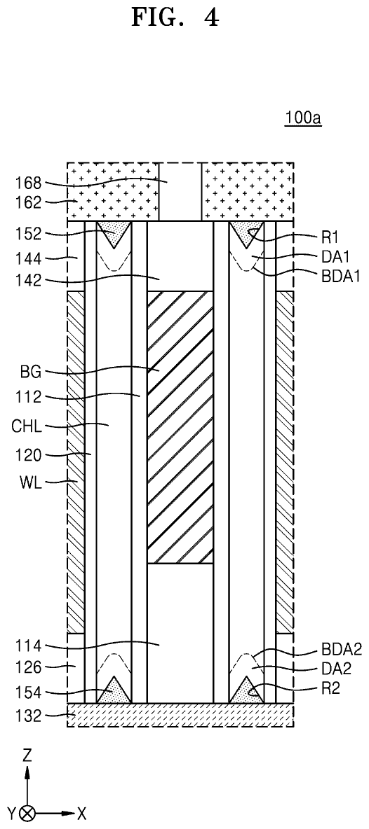

FIG. 4 is a cross-sectional view of a semiconductor memory device 100a according to some example embodiments. FIG. 4 illustrates an enlarged cross-sectional configuration of the semiconductor memory device 100a corresponding to a portion indicated as “EX1” in FIG. 2A. In FIG. 4, the same reference numerals as in FIGS. 1 to 3C indicate the same members, and duplicate descriptions thereof are omitted.

Referring to FIG. 4, the semiconductor memory device 100a may include a plurality of first contact pads 152 each filling a first recess R1 formed at a first end of each of a plurality of channel regions CHL, and a plurality of second contact pads 154 each filling a second recess R2 formed at a second end thereof opposite to the first end in the vertical direction (Z direction). The first recess R1, the plurality of first contact pads 152, and the first doped area DA1 of FIG. 4 are the same as the recess R1, the plurality of contact pads 152, and the doped area DA1 of the semiconductor memory device 100 described with reference to FIGS. 1 to 3C.

According to some example embodiments, the second recess R2 and the plurality of second contact pads 154 may have substantially the same structure as the first recess R1 and the plurality of first contact pads 152 except that the second recess R2 and the plurality of second contact pads 154 are arranged symmetrically in the vertical direction (Z direction) with the first recess R1 and the plurality of first contact pads 152, respectively. For example, the inner walls of the second recess R2 may include crystal planes having one or more directions. In some example embodiments, the inner walls of the first recess R1 and the inner walls of the second recess R2 may have the same crystal plane direction. In some example embodiments, the inner walls of the first recess R1 may have a different crystal plane direction than the inner walls of the second recess R2.

In some example embodiments, the plurality of second contact pads 154 may be disposed one by one between the plurality of channel regions CHL and the plurality of conductive lines BL. The second end of each of the plurality of channel regions CHL may be in contact with a corresponding second contact pad 154 among the plurality of second contact pads 154, and may face a corresponding conductive line BL among the plurality of conductive lines BL with the corresponding second contact pad 154 positioned in between.

In some example embodiments, a lower surface of each of the plurality of second contact pads 154 may be in contact with a corresponding conductive line BL among the plurality of conductive lines BL. In some example embodiments, a lowermost surface of each of the plurality of channel regions CHL may be positioned at the same vertical level as the lower surface of each of the plurality of second contact pads 154. In some example embodiments, the plurality of second contact pads 154 may each extend into a corresponding channel region CHL among the plurality of channel regions CHL, and may have sidewalls spaced apart from the back gate dielectric film 112 and the gate dielectric film 120 that contact a corresponding channel region CHL at a vertical level higher than the lower surface.

In some example embodiments, a width of each of the plurality of second contact pads 154 in the horizontal direction (X direction and/or second horizontal direction) may decrease away from the plurality of conductive lines BL. In some example embodiments, sidewalls of each of the plurality of second contact pads 154 may extend linearly, and each of the plurality of second contact pads 154 may have an edge pointing to a corresponding contact plug 160 among the plurality of contact plugs 160. For example, each of the plurality of second contact pads 154 may have the shape of a pentahedron, and one plane of the pentahedron may have a shape corresponding to the planar shape of each of the plurality of channel regions CHL. For example, first edges of the plurality of first contact pads 152 may be arranged to face second edges of the plurality of second contact pads 154 in the vertical direction (Z direction).

In some example embodiments, each of the plurality of channel regions CHL may include a first doped area DA1 in contact with the first contact pad 152 and a second doped area DA2 in contact with the second contact pad 154. The second doped area DA2 as an area doped with a dopant may function as a source/drain area. In some example embodiments, a boundary BDA2 of the second doped area DA2 may correspond to the shape of the sidewalls of each of the plurality of second contact pads 154. For example, a concentration contour line of the dopant in the second doped area DA2 may have a profile similar to that obtained by moving the surface of the sidewalls of each of the plurality of second contact pads 154 in parallel in the vertical direction (Z direction). For example, the boundary BDA2 of the second doped area DA2 may have a curved surface that is convex toward the conductive contact plug 160, which is similar to the shape of the second edge of the plurality of second contact pads 154 which points to the conductive contact plug 160. For example, a portion of the boundary BDA2 of the second doped area DA2 that overlaps with the second edge of the plurality of second contact pads 154 in the vertical direction (Z direction) may be located at a higher vertical level than portions of the boundary BDA2 of the second doped area DA2 that is in contact with the back gate dielectric film 112 and the gate dielectric film 120 which are adjacent to a corresponding channel region CHL of the plurality of channel regions CHL.

In FIG. 4, it is illustrated that the first doped area DA1 and the boundary BDA1 of the first doped area DA1 have the same thickness and shape as the second doped area DA2 and the boundary BDA2 of the second doped area DA2, respectively, but is not limited thereto. For example, a concentration profile of the dopant in the second doped area DA2 may be different from that of the dopant in the first doped area DA1.

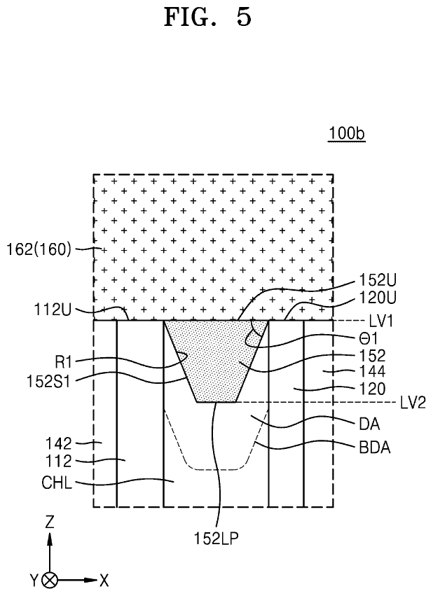

FIG. 5 is a cross-sectional view of a semiconductor memory device 100b according to some example embodiments. FIG. 5 illustrates an enlarged cross-sectional configuration of the semiconductor memory device 100b corresponding to a portion indicated as “EX2” in FIG. 3A. In FIG. 5, the same reference numerals as in FIGS. 1 to 3C indicate the same members, and duplicate descriptions thereof are omitted.

Referring to FIG. 5, the plurality of contact pads 152 may have a lower surface 152LP that is parallel to the upper surface 152U thereof. In some example embodiments, the lower surface 152LP thereof which is a lowermost surface of the plurality of contact pads 152 may be positioned at the second vertical level LV2.

In some example embodiments, the inner walls of the recess R1 may have a first direction crystal plane, and the lower surface of the recess R1 may have a second direction crystal plane different from the first direction crystal plane. For example, the plurality of channel regions CHL may include Si, the inner walls of the recess R1 may include a (111) crystal plane, and the lower surface of the recess R1 may include a (100) crystal plane.

In some example embodiments, each of the plurality of contact pads 152 may have the shape of a frustum. For example, the first sidewalls 152S1 and the second sidewalls 152S2 (see FIG. 3C) of each of the plurality of contact pads 152 may each have the shape of an equilateral trapezoid.

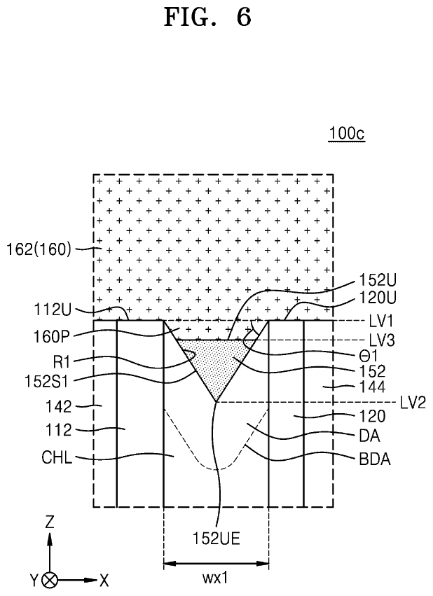

FIG. 6 is a cross-sectional view of a semiconductor memory device 100c according to some example embodiments. FIG. 6 illustrates an enlarged cross-sectional configuration of the semiconductor memory device 100c corresponding to a portion indicated as “EX2” in FIG. 3A. In FIG. 6, the same reference numerals as in FIGS. 1 to 4 indicate the same members, and duplicate descriptions thereof are omitted.

Referring to FIG. 6, the upper surface 152U of the plurality of contact pads 152 may be positioned at a third vertical level LV3 that is lower than the first vertical level LV1. In some example embodiments, each of the plurality of contact plugs 160 may include a protrusion 160P extending into a corresponding channel region CHL among the plurality of channel regions CHL. For example, the protrusion 160P may be a portion of the first conductive pattern 162 constituting each contact plug 160.

In some example embodiments, the protrusion 160P may fill a portion of the recess R1 on each of the plurality of contact pads 152. For example, the protrusion 160P may have a tapered shape such that a width of the protrusion 160P in the horizontal direction (X direction and/or direction) decreases toward the conductive line BL. In some example embodiments, sidewalls of the protrusion 160P may be linearly extended to continuously extend from the sidewalls 152S1 and 152S2 of the corresponding contact pad 152 among the plurality of contact pads 152.

In some example embodiments, the plurality of contact pads 152 may be spaced apart from the adjacent back gate dielectric film 112 and gate dielectric film 120, respectively, in the horizontal direction (X direction and/or Y direction). The width of the upper surface 152U of the plurality of contact pads 152 in the first horizontal direction (X direction) may be smaller than the first width wx1, and the width of the upper surface 152U of the plurality of contact pads 152 in the second horizontal direction (Y direction) may be smaller than the second width wyL.

In some example embodiments, the protrusion 160P may be surrounded by the corresponding channel region CHL, and, below the first vertical level LV1, the sidewalls of the protrusion 160P may be spaced apart from the back gate dielectric film 112 and the gate dielectric film 120 adjacent to the corresponding channel region CHL with the corresponding channel region CHL positioned in between.

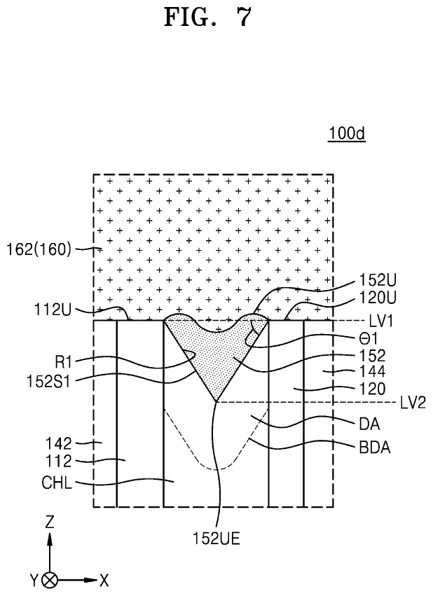

FIG. 7 is a cross-sectional view of a semiconductor memory device 100d according to some example embodiments. FIG. 7 illustrates an enlarged cross-sectional configuration of the semiconductor memory device 100d corresponding to a portion indicated as “EX2” in FIG. 3A. In FIG. 7, the same reference numerals as in FIGS. 1 to 3C indicate the same members, and duplicate descriptions thereof are omitted.

Referring to FIG. 7, the upper surface 152U of each of the plurality of contact pads 152 may have an uneven shape. In some example embodiments, each of the plurality of contact pads 152 may include a portion (e.g., an upper portion) positioned at a vertical level higher than the first vertical level LV1 and a portion (e.g., a lower portion) positioned at a vertical level lower than the first vertical level LV1. In some example embodiments, each of the plurality of contact pads 152 may cover the inner walls of the recess R1 and partially fill the recess R1. The first conductive pattern 162 of the corresponding contact plug 160 among the plurality of contact plugs 160 may be positioned on the contact pad 152 and may fill the remaining portion of the recess R1.

In some example embodiments, the lower surface of the plurality of contact plugs 160 may have a profile corresponding to the upper surface 152U of the plurality of contact pads 152. For example, the plurality of contact plugs 160 may include a protrusion positioned at a vertical level lower than the first vertical level LV1, and the protrusion may be surrounded by the corresponding contact pad 152.

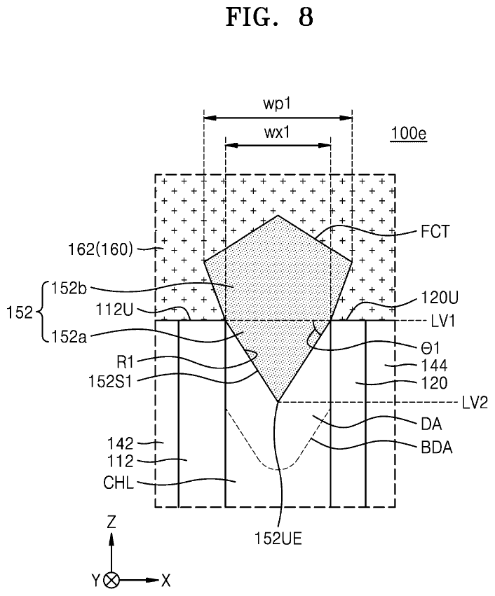

FIG. 8 is a cross-sectional view of a semiconductor memory device 100e according to some example embodiments. FIG. 8 illustrates an enlarged cross-sectional configuration of the semiconductor memory device 100e corresponding to a portion indicated as “EX2” in FIG. 3A. In FIG. 8, the same reference numerals as in FIGS. 1 to 3C indicate the same members, and duplicate descriptions thereof are omitted.

Referring to FIG. 8, each of the plurality of contact pads 152 may include a lower portion 152a positioned at a vertical level lower than the first vertical level LV1 and surrounded by a corresponding channel region CHL among the plurality of channel regions CHL, and an upper portion 152b positioned at a vertical level higher than the first vertical level LV1 and surrounded by a first conductive pattern 162 of a corresponding contact plug 160 among the plurality of contact plugs 160. For example, the lower portion 152a may fill the recess R1 and contact the corresponding channel region CHL. For example, the upper portion 152b may extend from the lower portion 152a into the first conductive pattern 162. In FIG. 8, first sidewalls 152S1 represent sidewalls of the lower portion 152a in the first horizontal direction (X direction). The upper portion 152b may have a third sidewall FCT in contact with the contact plug 160.

In some example embodiments, at the boundary between the lower portion 152a and the upper portion 152b, the slope of the sidewalls of each of the plurality of contact pads 152 may vary discontinuously. For example, the slope of the first sidewalls 152S1 of the lower portion 152a may be different from the slope of the third sidewalls FCT of the upper portion 152b, and the slope of the first sidewalls 152S1 and the slope of the third sidewalls FCT may be discontinuous at the boundary between the lower portion 152a and the upper portion 152b.

In some example embodiments, the plurality of contact pads 152 may include a semiconductor film epitaxially grown on the inner walls of the recess R1, and the third sidewalls FCT of the upper portion 152b may have a facet grown in a crystal direction of the epitaxial semiconductor film. Although not shown, sidewalls (not shown) of the upper portion 152b in the second horizontal direction (Y direction) may also have a facet grown in the crystal direction.

In some example embodiments, and as shown in FIG. 8, the upper portion 152b of each of the plurality of contact pads 152 may include a first portion whose width in the horizontal direction (X direction and/or Y direction) increases away from the plurality of conductive lines BL, and a second portion whose width in the horizontal direction (X direction and/or Y direction) decreases away from the plurality of conductive lines BL, wherein the second portion extends from the first portion. For example, the first portion may extend from the lower portion 152a. In some example embodiments, the upper portion 152b may include an extended portion that is wider in the horizontal direction (X direction and/or Y direction) than the lower portion 152a. For example, a third width wp1, which is a width of the extended portion in the first horizontal direction (X direction), may be greater than the first width wx1. Although not shown, a width of the extended portion in the second horizontal direction (Y direction) may be greater than the second width wy1 (see FIG. 3C). In some example embodiments, the extended portion may include portions that overlap with the back gate dielectric film 112 and the gate dielectric film 120 adjacent to the corresponding channel region CHL in the vertical direction (Z direction).

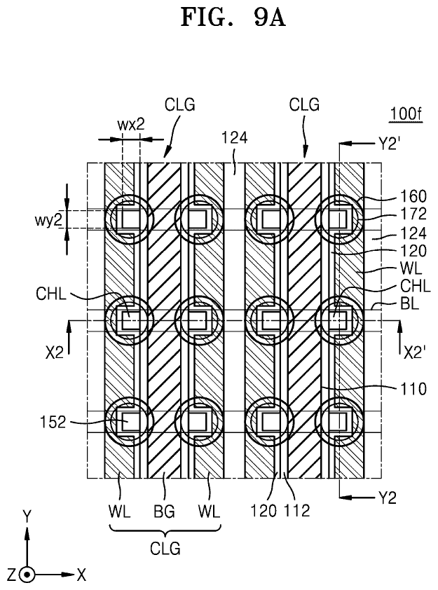

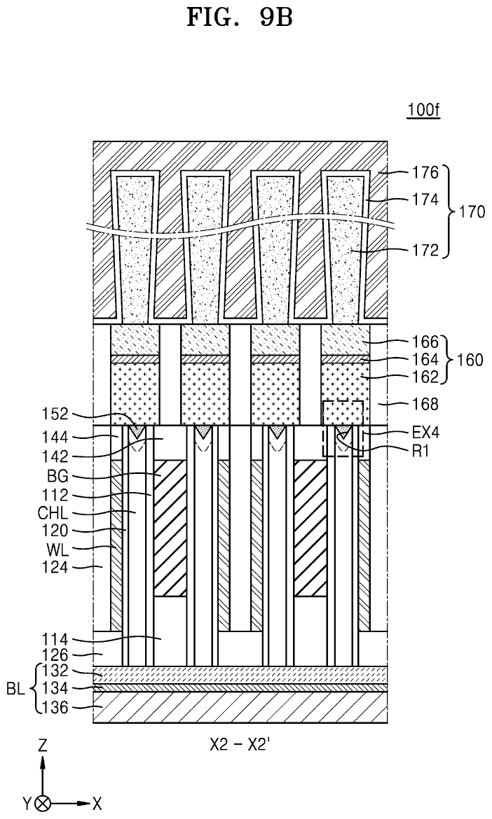

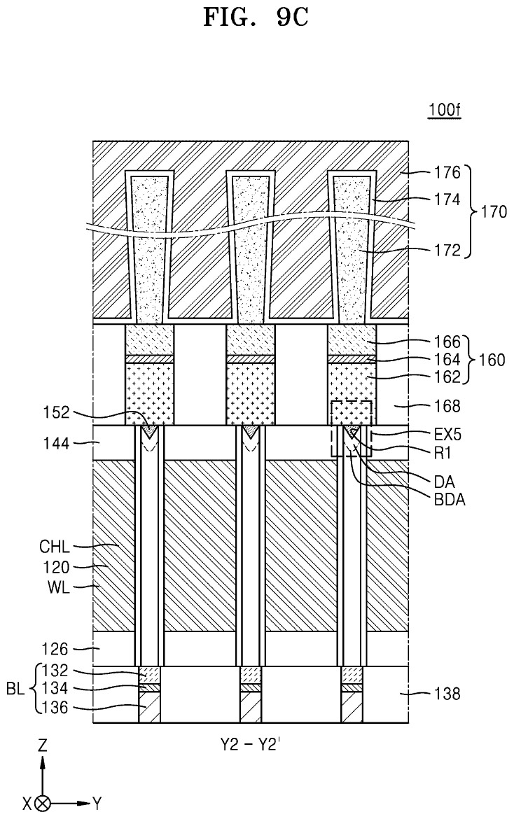

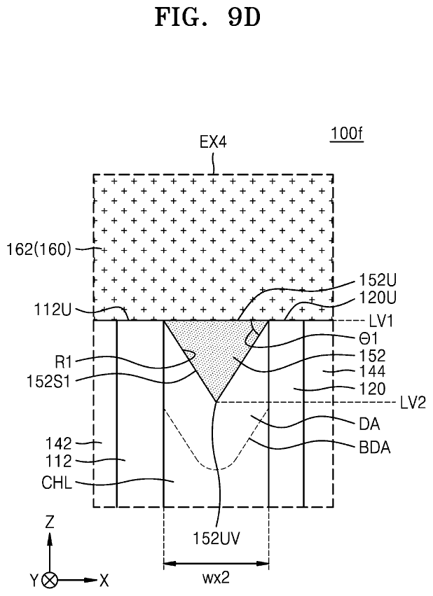

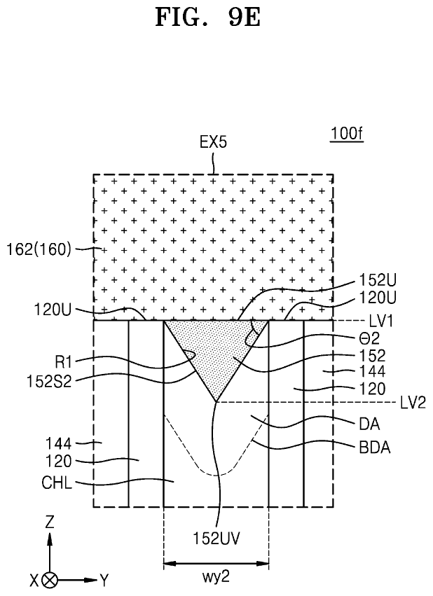

FIG. 9A is a plan layout diagram of a partial configuration of a semiconductor memory device 100f according to some example embodiments. FIG. 9B is a cross-sectional view taken along line X2-X2′ of FIG. 9A, and FIG. 9C is a cross-sectional view taken along line Y2-Y2′ of FIG. 9A. FIG. 9D is an enlarged view of a portion indicated as “EX4” in FIG. 9B, and FIG. 9E is an enlarged view of a portion indicated as “EX5” in FIG. 9C. In FIGS. 9A to 9E, the same reference numerals as in FIGS. 1 to 3C indicate the same members, and duplicate descriptions thereof are omitted.

Referring to FIGS. 9A to 9E, the plurality of channel regions CHL may have a fourth width wx2 in the first horizontal direction (X direction) and a fifth width wy2 in the second horizontal direction (Y direction), and may extend in the vertical direction (Z direction). At the first vertical level LV1, the width of each of the plurality of contact pads 152 in the first horizontal direction (X direction) may be substantially the same as the fourth width wx2, and the width of each of the plurality of contact pads 152 in the second horizontal direction (Y direction) may be substantially the same as the fifth width wy2.

In some example embodiments, the fourth width wx2 may be the same as the fifth width wy2. In some example embodiments, the first sidewalls 152S1 and the second sidewalls 152S2 of each of the plurality of contact pads 152 may meet at the second vertical level LV2 to form a vertex 152UV. For example, the upper surface 152U of each of the plurality of contact pads 152 may have the shape of a square plane, and the first sidewalls 152S1 and the second sidewalls 152S2 may each have the shape of an equilateral trapezoid. For example, the plurality of contact pads 152 may each have the shape of a square pyramid with a base at the first vertical level LV1 and a vertex 152UV at the second vertical level LV2.

Hereinafter, a method of manufacturing a semiconductor memory device according to some example embodiments are described using specific examples.

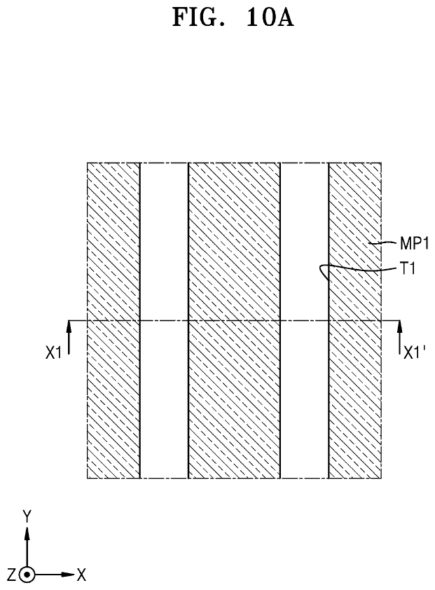

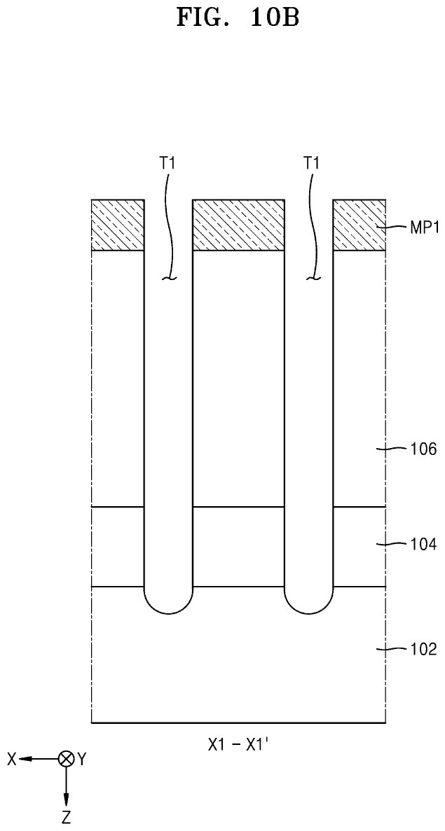

FIGS. 10A, 10B, 11, 12A, 12B, 13, 14A, 14B, 15A, 15B, 16, 17, 18A, 18B, 19, 20, 21, 22, 23, 24, 25, and 26 are diagrams showing a process sequence to explain a method of manufacturing the semiconductor memory device 100 according to some example embodiments. More specifically, FIGS. 10A, 12A, 14A, 15A, and 18A are plan layout diagrams of partial configurations according to a process sequence to explain a method of manufacturing a semiconductor memory device. FIGS. 10B, 11, 12B, 13, 14B, 15B, 16, 17, 18B, 19, 20, 21, 22, 23, 24, 25, and 26 are cross-sectional views of a portion corresponding to line X1-X1′ of FIG. 1 according to a process sequence. Referring to FIGS. 10A to 26, a method of manufacturing the semiconductor memory device 100 illustrated in FIGS. 1 to 3C is described. In FIGS. 10A to 26, the same reference numerals as in FIGS. 1 to 3C indicate the same members, and duplicate descriptions thereof are omitted.

Referring to FIGS. 10A and 10B, a substrate structure including a substrate 102, a buried insulating film 104, and an active layer 106 may be prepared.

The substrate structure may be a silicon on insulator (SOI) substrate. The substrate 102 may be a silicon substrate. The buried insulating film 104 may include a silicon oxide film. The active layer 106 may include at least one selected from Ge, SiGe, SiC, GaAs, InAs, and InP. In some example embodiments, the active layer 106 may include a well doped with impurities or a structure doped with impurities.

A mask pattern MP1 may be formed on the active layer 106 of the substrate structure. The mask pattern MP1 may include a silicon nitride film. In some example embodiments, an oxide film may be positioned between the active layer 106 and the mask pattern MP1.

Using the mask pattern MP1 as an etch mask, partial regions of the substrate structure may be etched to form a plurality of first trenches T1. The plurality of first trenches T1 may be formed to penetrate the active layer 106 and the buried insulating film 104 in the vertical direction (Z direction) and extend long in the second horizontal direction (Y direction).

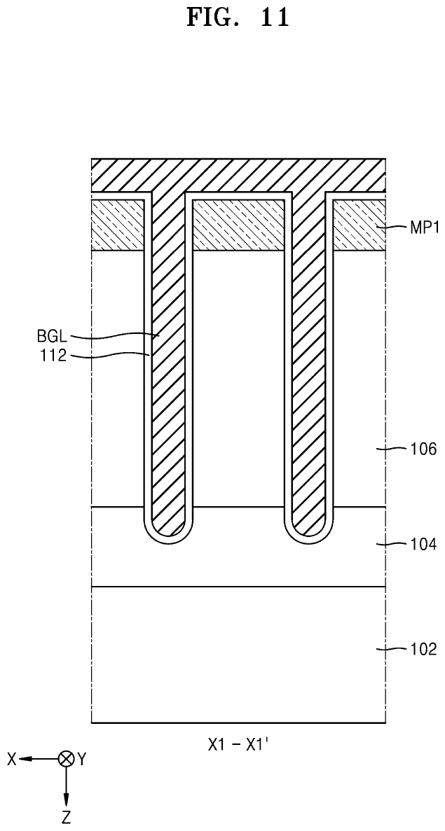

Referring to FIG. 11, a back gate dielectric film 112 that conformally covers each surface of inner walls of the plurality of first trenches T1 and the mask pattern MP1 and a back gate conductive layer BGL filling the plurality of first trenches T1 on the back gate dielectric film 112 may be formed from the result shown in FIGS. 10A and 10B. The constituent material of the back gate conductive layer BGL is substantially the same as the constituent material of the back gate electrode BG described above.

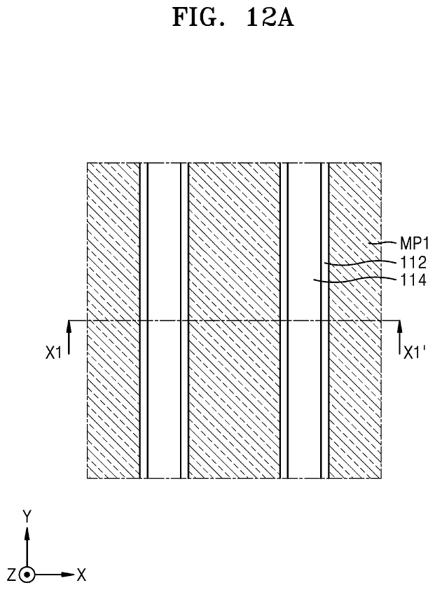

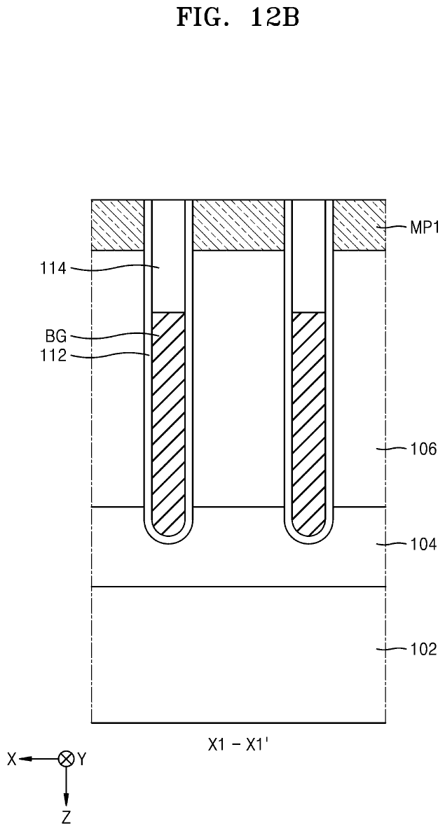

Referring to FIGS. 12A and 12B, from the result shown in FIG. 11, the plurality of back gate electrodes BG may be formed in the plurality of first trenches T1 by etching the back gate conductive layer BGL, and the upper space of each of the plurality of first trenches T1 may be filled with the second capping insulating pattern 114, which is flattened to expose the upper surface of the mask pattern MP1.

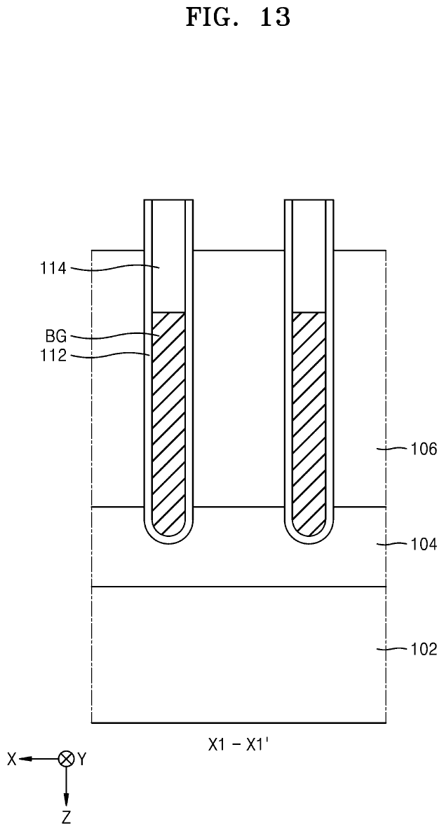

Referring to FIG. 13, by removing the mask pattern MP1 from the result of FIGS. 12A and 12B, the active layer 106 may be exposed around the plurality of second capping insulating patterns 114 and the plurality of back gate dielectric films 112.

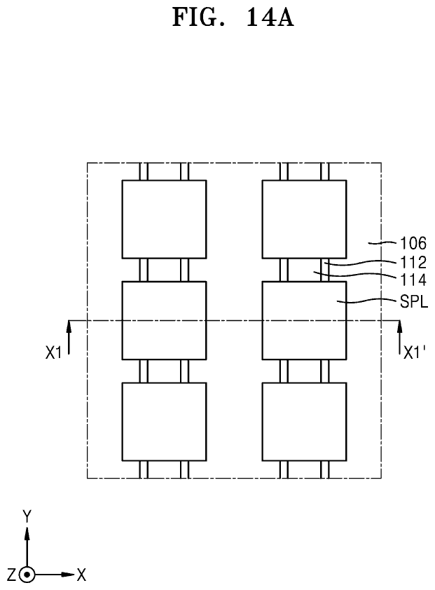

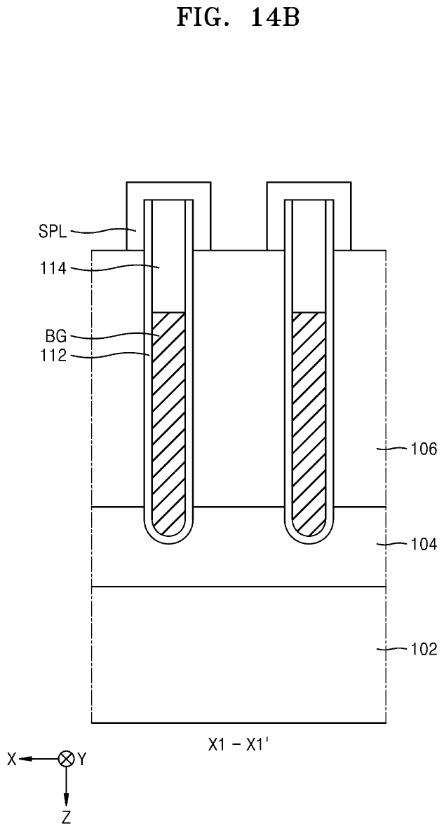

Referring to FIGS. 14A and 14B, a plurality of spacer layers SPL may be formed to cover a partial area of each of the plurality of second capping insulating patterns 114 and the plurality of back gate dielectric films 112 and a partial area of the active layer 106 adjacent thereto. Each of the plurality of spacer layers SPL may include a silicon oxide film. The plurality of spacer layers SPL may include a first group of spacer layers SPL arranged in a row in the first horizontal direction (X direction) and spaced apart from each other in the first horizontal direction (X direction), and a second group of spacer layers SPL arranged in a row in the second horizontal direction (Y direction) and spaced apart from each other in the second horizontal direction (Y direction).

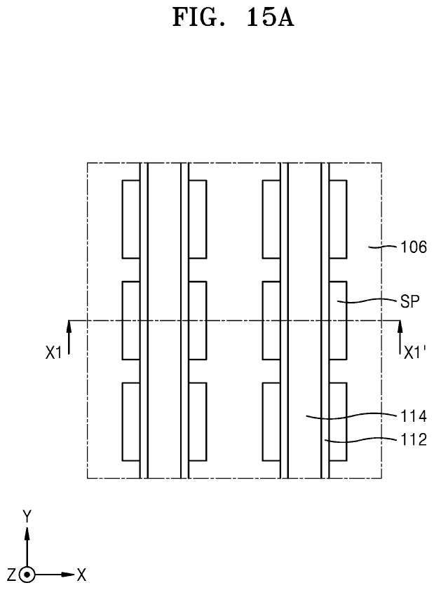

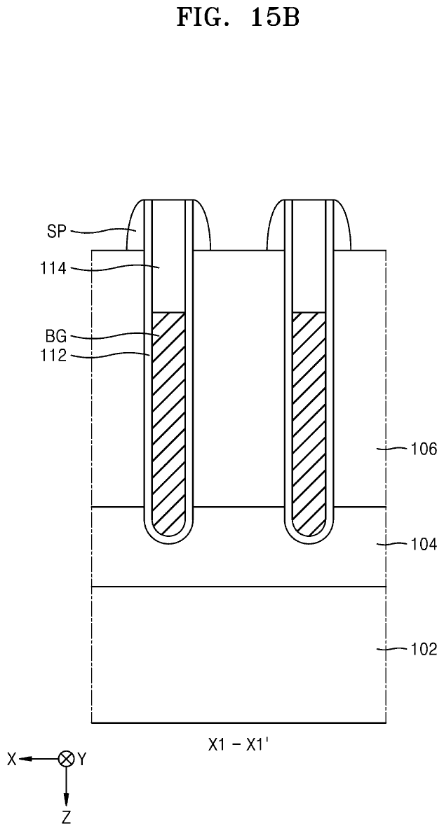

Referring to FIGS. 15A and 15B, by etching back the plurality of spacer layers SPL, a plurality of spacers SP may be formed to cover both sidewalls of each of the plurality of structures including the second capping insulating pattern 114 and the back gate dielectric film 112 in the first horizontal direction (X direction). The upper surface of the active layer 106 adjacent to the structure may be partially covered by the plurality of spacers SP.

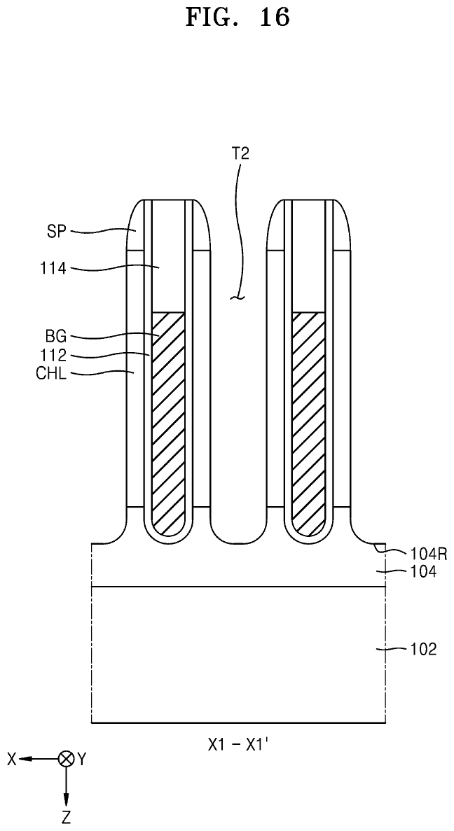

Referring to FIG. 16, from the result of FIGS. 15A and 15B, the active layer 106 may be etched using the plurality of second capping insulating patterns 114, the plurality of back gate dielectric films 112, and the plurality of spacers SP as an etch mask to form a plurality of second trenches T2. As a result, portions of the active layer 106 below the spacers SP may remain as a plurality of channel regions CHL. In the process of etching the active layer 106, portions of the buried insulating film 104 may be etched by excessive etching, thereby forming a plurality of recess regions 104R connected to the plurality of second trenches T2 on the upper surface of the buried insulating film 104.

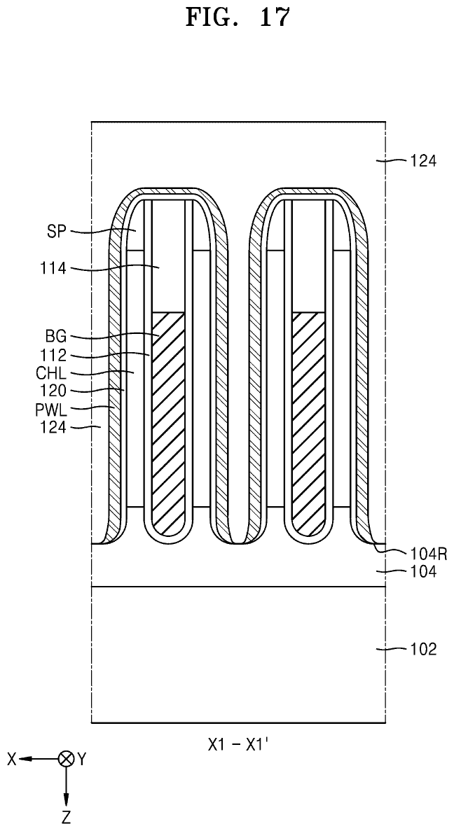

Referring to FIG. 17, after forming a gate dielectric film 120 that conformally covers the result of FIG. 16 and forming a conductive layer that conformally covers the gate dielectric film 120, portions of the conductive layer in the recess region 104R of the buried insulating film 104 may be etched to separate the conductive layer into a plurality of preliminary word lines PWL. Afterwards, a separation insulating pattern 124 may be formed to fill the upper space of the plurality of preliminary word lines PWL. The separation insulating pattern 124 may be formed to fill the space between each of the plurality of preliminary word lines PWL and cover the upper surface of each of the plurality of preliminary word lines PWL. The constituent material of the conductive layer is the same as the constituent material of the word line WL described above.

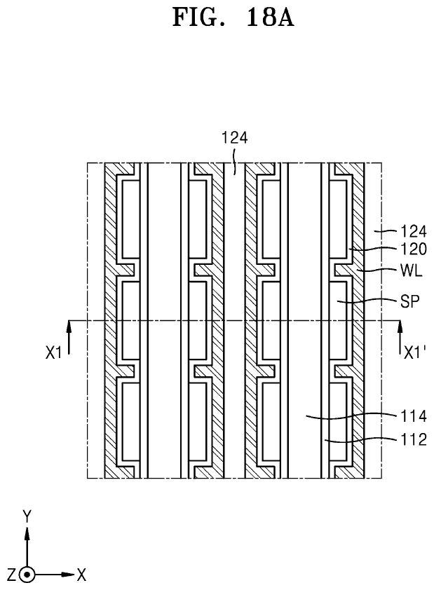

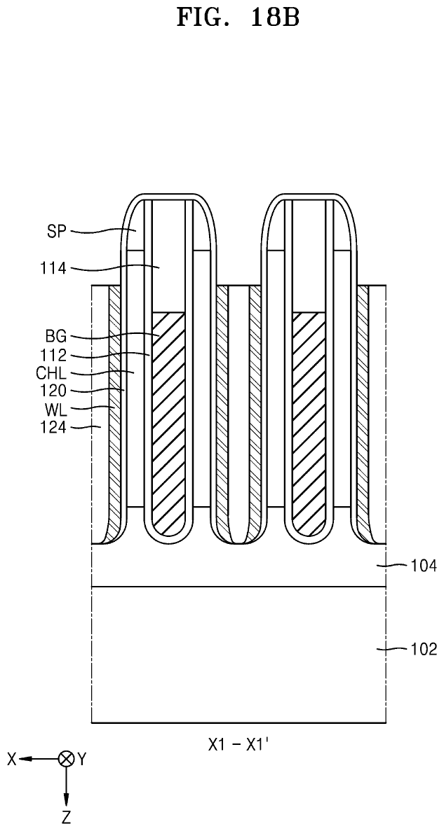

Referring to FIGS. 18A and 18B, from the result of FIG. 17, the upper part of the separation insulating pattern 124 may be partially removed by etching back the separation insulating pattern 124, thereby exposing a portion of each of the plurality of preliminary word lines PWL, and a plurality of word lines WL may be formed by etching each of the exposed preliminary word lines PWL.

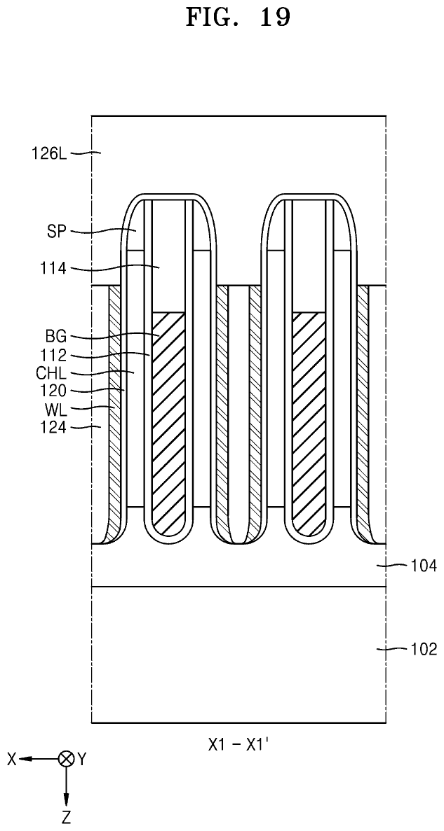

Referring to FIG. 19, a buried insulating film 126L may be formed to cover the result of FIGS. 18A and 18B. The constituent material of the buried insulating film 126L is the same as the constituent material of the second buried insulating pattern 126 described above.

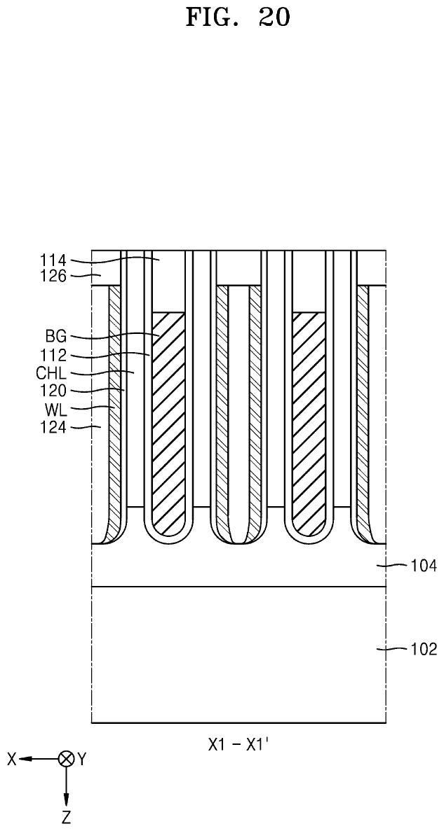

Referring to FIG. 20, from the result of FIG. 19, a planarization process may be performed on the exposed upper surface of the buried insulating film 126L to expose the plurality of channel regions CHL, and the second buried insulating pattern 126 may be formed from the buried insulating film 126L. After exposing the plurality of channel regions CHL, a top height of each of the second capping insulating pattern 114 and the gate dielectric film 120 in the result of FIG. 18 may be lowered.

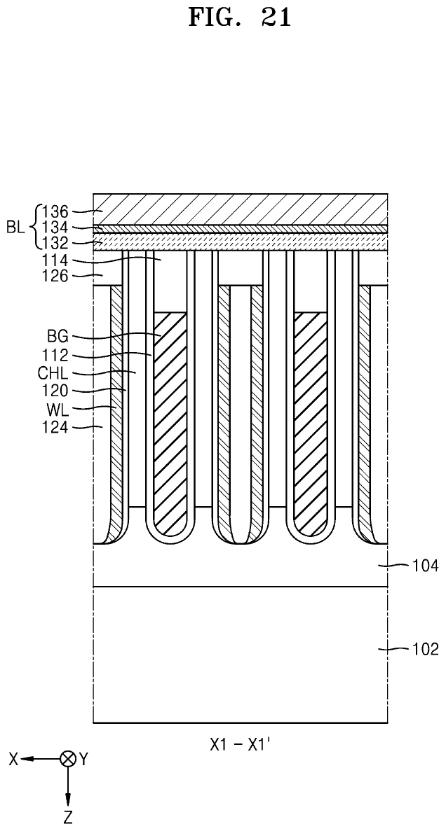

Referring to FIG. 21, from the result of FIG. 20, the first conductive line 132, the second conductive line 134, and the third conductive line 136 may be sequentially formed on the upper surface of the second capping insulating pattern 114, the upper surface of the second buried insulating pattern 126, the upper surface of the back gate dielectric film 112, and the upper surface of the gate dielectric film 120, thereby forming the plurality of conductive lines BL. Although not shown, the plurality of conductive lines BL may be spaced apart from each other in the second horizontal direction (Y direction) with the first interlayer insulating film 138 positioned in between.

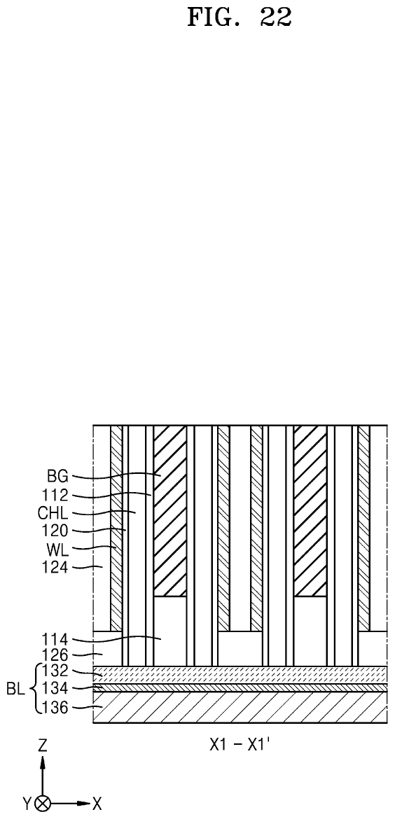

Referring to FIG. 22, the substrate 102 may directed upward in the vertical direction (Z direction) from the result of FIG. 21 by flipping the result of FIG. 21 so that the upper and lower directions in the vertical direction (Z direction) become opposite, and a grinding process and a wet etching process may be sequentially performed on the exposed backside surface of the substrate 102 until the plurality of channel regions CHL are exposed.

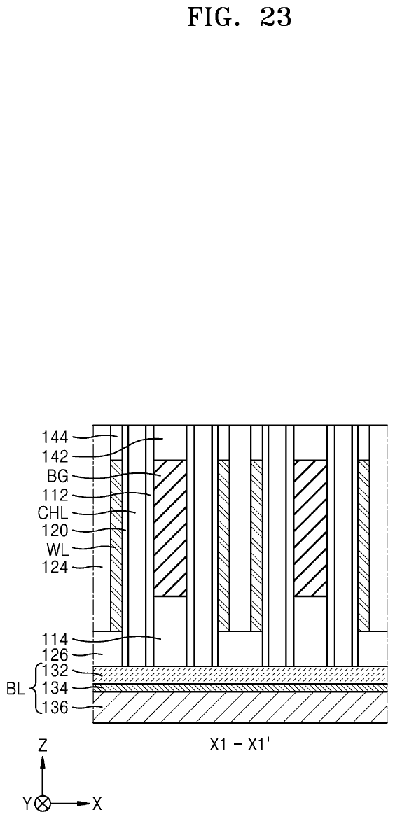

Referring to FIG. 23, a plurality of spaces may be provided by removing a portion of each of the plurality of back gate electrodes BG and the plurality of word lines WL which are exposed in the result of FIG. 22, and a plurality of first capping insulating patterns 142 and a plurality of first buried insulating patterns 144 may be formed to fill the plurality of spaces.

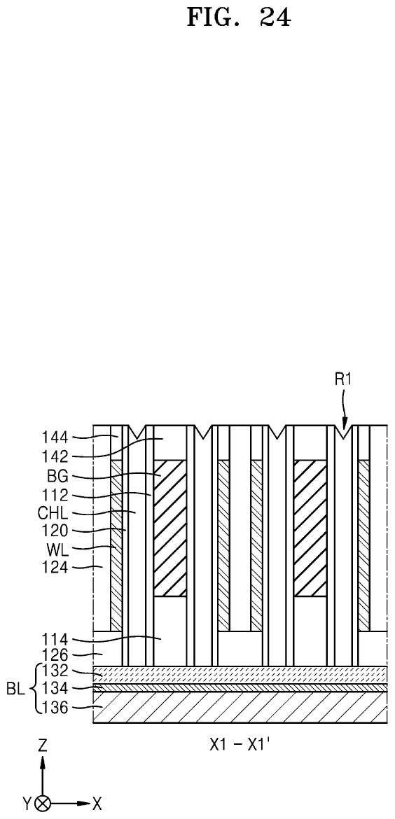

Referring to FIG. 24, from the result of FIG. 23, the exposed upper surfaces of the plurality of channel regions CHL may be treated with a pretreatment solution containing hydroxyl group (—OH), and then, the plurality of channel regions CHL may be partially removed through wet etching using an etchant to form a recess R1. The plurality of channel regions CHL treated with the pretreatment solution may exhibit different etching rates with respect to the etchant depending on the direction of a crystal plane. For example, the plurality of channel regions CHL may include a (100) plane, a (110) plane, and a (111) plane, and after being treated with the pretreatment solution, the etching rates of the (100) plane and (110) plane for the etchant may be significantly higher than the etching rate for the (111) plane. In this case, the (111) plane may function as an etch stop plane, and the inner walls of the recess R1 may have the (111) plane. Due to differences in etching rate depending on the direction of the crystal plane, the recess R1 may be formed to become deeper from the edge toward the center so that the back gate dielectric film 112 and the gate dielectric film 120 covering the upper portion of the channel region CHL are not exposed. In a method of manufacturing a semiconductor memory device according to some example embodiments, using the difference in etching rate depending on the crystal plane, a recess may be formed to adjust a joint depth by removing the upper portion of the extremely thin channel region CHL, and the sidewalls of the back gate dielectric film 112 and the gate dielectric film 120 may not be exposed.

In some example embodiments, the pretreatment solution may be, for example, NH4OH. In some example embodiments, the pretreatment solution and the etchant may be used in different orders. In some example embodiments, the pretreatment solution and the etchant may be used together.

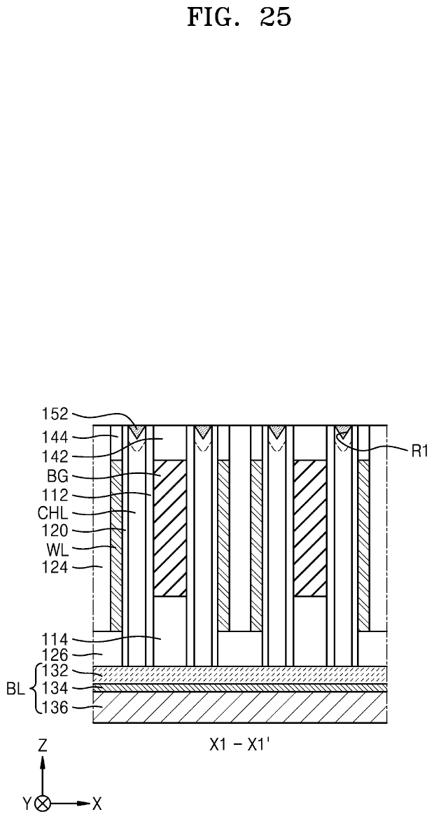

Referring to FIG. 25, from the result of FIG. 24, a semiconductor film, for example, SiAsP, containing a dopant may be epitaxially grown from the channel region CHL exposed through the recess R1, and then planarized through etch-back to form the plurality of contact pads 152.

In some example embodiments, when the semiconductor film is more removed through the etch-back than that shown in FIG. 25, the semiconductor memory device 100c described with reference to FIG. 6 may be formed. In some example embodiments, when the etch-back process is omitted after growing the semiconductor film, the semiconductor memory device 100d described with reference to FIG. 7 or the semiconductor memory device 100e described with reference to FIG. 8 may be manufactured.

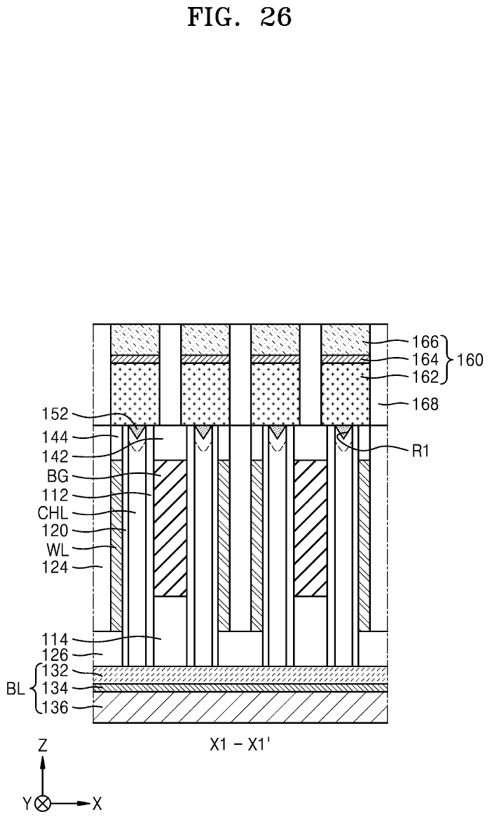

Referring to FIG. 26, from the result of FIG. 25, the plurality of contact plugs 160 may be formed on the contact pads 152, and a second interlayer insulating film 168 may be formed to fill the space between each of the plurality of contact plugs 160.

Referring to FIGS. 26, 2A, and 2B together, the semiconductor memory device 100 described with reference to FIGS. 1 to 3C may be manufactured by forming a capacitor structure 170 connected to the plurality of contact plugs 160 on the result of FIG. 26.

Although methods of manufacturing the semiconductor memory device 100 illustrated in FIGS. 1 to 3C have been described with reference to FIGS. 9A to 26, those skilled in the art may understand that semiconductor memory devices having various structures that are variously modified from the semiconductor memory device 100 illustrated in FIGS. 1 to 3C may be manufactured by applying various modifications and changes within the scope of the inventive concepts.

While the inventive concepts have been particularly shown and described with reference to some example embodiments thereof, it will be understood that various changes in form and details may be made therein without departing from the spirit and scope of the following claims.

What is claimed is:

1. A semiconductor memory device, comprising:
a conductive line extending longitudinally in a first horizontal direction;
a plurality of channel regions spaced apart from each other in the first horizontal direction on the conductive line, the plurality of channel regions each defining a separate recess at an upper end thereof;
a plurality of contact plugs spaced apart from the conductive line in a vertical direction such that the plurality of channel regions are between the plurality of contact plugs and the conductive line in the vertical direction, the vertical direction perpendicular to the first horizontal direction;
a back gate electrode extending longitudinally in a second horizontal direction between a first channel region and a second channel region which are adjacent to each other and selected from among the plurality of channel regions, the second horizontal direction perpendicular to both the first horizontal direction and the vertical direction;
a back gate dielectric film between the back gate electrode and the first channel region;
a word line spaced apart from the back gate electrode in the first horizontal direction such that the first channel region is between the word line and the back gate electrode;
a gate dielectric film between the word line and the first channel region; and
a first contact pad that at least partially fills a recess defined by the first channel region and contacts a first contact plug selected from among the plurality of contact plugs and at least partially overlapping the first channel region in the vertical direction,
wherein an uppermost surface of the first channel region is at a first vertical level, and sidewalls of the first contact pad are spaced apart from the back gate dielectric film and the gate dielectric film such that the first channel region includes a first portion between the first contact pad and the back gate dielectric film, and a second portion between the first contact pad and the gate dielectric film.

2. The semiconductor memory device of claim 1, wherein
a width of the first contact pad in the first horizontal direction decreases toward the conductive line, and
opposite sidewalls of the first contact pad in the first horizontal direction meet at a second vertical level lower than the first vertical level to form an edge.

3. The semiconductor memory device of claim 2, wherein
a width of the first contact pad in the second horizontal direction decreases toward the conductive line, and
opposite sidewalls of the first contact pad in the second horizontal direction contact opposite ends of the edge, respectively, at the second vertical level.

4. The semiconductor memory device of claim 1, wherein the sidewalls of the first contact pad extend linearly.

5. The semiconductor memory device of claim 1, wherein the first contact pad is in line contact with the back gate dielectric film and the gate dielectric film at the first vertical level.

6. The semiconductor memory device of claim 1, wherein the first contact pad comprises a semiconductor film doped with a dopant.

7. The semiconductor memory device of claim 1, wherein
the first channel region comprises a doped area, the doped area in contact with the first contact pad and doped with a dopant, and
a concentration contour line of the dopant in the doped area has a curved surface that is convex toward the conductive line to correspond to a shape of the first contact pad.

8. The semiconductor memory device of claim 1, wherein
an upper surface of the first contact pad is at a second vertical level lower than the first vertical level, and
the first contact plug comprises a protrusion that partially fills the recess on the first contact pad and is surrounded by the first channel region.

9. The semiconductor memory device of claim 1, wherein the first contact pad comprises
a lower portion surrounded by an upper end of the first channel region, and
an upper portion extending into the contact plug on the first channel region.

10. The semiconductor memory device of claim 9, wherein
the first contact pad comprises an epitaxial semiconductor film, and
the upper portion of the first contact pad has a facet grown in a crystal direction of the epitaxial semiconductor film.

11. The semiconductor memory device of claim 9, wherein
the first contact pad comprises an epitaxial semiconductor film, and
the upper portion of the first contact pad comprises:
a first portion extending from the lower portion of the first contact pad, the first portion having a width in the first horizontal direction that increases away from the conductive line; and
a second portion extending from the first portion, the second portion having a width in the first horizontal direction that decreases away from the conductive line.

12. The semiconductor memory device of claim 1, wherein inner walls of the recess comprise a first direction crystal plane.

13. The semiconductor memory device of claim 1, further comprising a second contact pad surrounded by a lower end of the first channel region and extending into the lower end,
wherein a lowermost surface of the lower end of the first channel region and a lower surface of the second contact pad are at a second vertical level, and
wherein a sidewall of the second contact pad is spaced apart from the back gate dielectric film and the gate dielectric film at a vertical level higher than the second vertical level.

14. A semiconductor memory device, comprising:
a conductive line extending longitudinally in a first horizontal direction;
a back gate line above the conductive line, the back gate line spaced apart from the conductive line and extending longitudinally in a second horizontal direction perpendicular to the first horizontal direction;
a first channel region and a second channel region respectively on opposite sides of the back gate line in the first horizontal direction;
a word line above the conductive line, the word line spaced apart from the conductive line and spaced apart from the back gate line in the first horizontal direction such that the first channel region is between the conductive line and the back gate line in the first horizontal direction;
a contact plug spaced apart from the conductive line in a vertical direction such that the first channel region is between the contact plug and the conductive line in the vertical direction, the vertical direction perpendicular to both the first horizontal direction and the second horizontal direction;
a first dielectric film extending in the vertical direction between the first channel region and the back gate line and contacting the contact plug and the conductive line;
a second dielectric film extending in the vertical direction between the first channel region and the word line and contacting the contact plug and the conductive line; and
a first contact pad having an upper surface in contact with the contact plug, the first contact pad extending into the first channel region such that a width of the first contact pad in the first horizontal direction and a width of the first contact pad in the second horizontal direction decrease away from the contact plug,
wherein an uppermost surface of the first channel region is located at a same vertical level as both an upper surface of the first dielectric film and an upper surface of the second dielectric film.

15. The semiconductor memory device of claim 14, wherein the first channel region comprises a first portion between the first contact pad and the first dielectric film, and a second portion between the first contact pad and the second dielectric film.

16. The semiconductor memory device of claim 14, wherein
first sidewalls of the first contact pad in the first horizontal direction extend linearly,
second sidewalls of the first contact pad in the second horizontal direction extend linearly, and
the first contact pad has a vertex at a point where the first sidewalls meet the second sidewalls.

17. A semiconductor memory device, comprising:
a plurality of conductive lines extending longitudinally in a first horizontal direction and spaced apart from each other in a second horizontal direction perpendicular to the first horizontal direction;
a plurality of contact plugs spaced apart from the plurality of conductive lines in a vertical direction, the vertical direction perpendicular to both the first horizontal direction and the second horizontal direction;
a plurality of channel regions positioned between the plurality of conductive lines and the plurality of contact plugs, each channel region of the plurality of channel regions including a first end connected to one conductive line of the plurality of conductive lines and a second end connected to one contact plug selected from among the plurality of contact plugs;
a plurality of back gate electrodes extending in the second horizontal direction between the plurality of conductive lines and the plurality of contact plugs, the plurality of back gate electrodes spaced apart from each other in the first horizontal direction;
a plurality of word lines extending longitudinally in the second horizontal direction between the plurality of conductive lines and the plurality of contact plugs and spaced apart from one selected from among the plurality of channel regions and one selected from among the plurality of back gate electrodes;
a back gate dielectric film between a first back gate electrode selected from among the plurality of back gate electrodes and a first channel region selected from among the plurality of channel regions;
a gate dielectric film between the first channel region and a first word line selected from among the plurality of word lines, the gate dielectric film spaced apart from the first back gate electrode such that the first channel region is between the gate dielectric film and the first back gate electrode; and
a plurality of contact pads, each contact pad of the plurality of contact pads at least partially between the plurality of channel regions and the plurality of contact plugs, each contact pad of the plurality of contact pads including a portion extending into the plurality of channel regions,
wherein an uppermost surface of the first end is at a first vertical level, and a first contact pad selected from among the plurality of contact pads is spaced apart from both the back gate dielectric film and the gate dielectric film at a vertical level lower than the first vertical level.

18. The semiconductor memory device of claim 17, wherein an upper surface of the back gate dielectric film and an upper surface of the gate dielectric film are both located at the first vertical level.

19. The semiconductor memory device of claim 17, wherein
a width of the first contact pad in the first horizontal direction and a width of the first contact pad in the second horizontal direction decrease away from the contact plug,
opposite sidewalls of the first contact pad in the first horizontal direction meet at a second vertical level lower than the first vertical level to form an edge extending in the second horizontal direction, and
opposite sidewalls of the first contact pad in the second horizontal direction contact opposite ends of the edge, respectively, at the second vertical level.

20. The semiconductor memory device of claim 17, wherein the plurality of contact pads include SiAsP.
